(19) United States
(12) Patent Application Publication
(10) Pub. No.: US 2013/0009327 A1
(43) Pub. Date: Jan. 10, 2013

(54) RESIN COMPOSITION FOR SEMICONDUCTOR ENCAPSULATION, AND SEMICONDUCTOR DEVICE USING SAME

(76) Inventor: Yusuke Tanaka, Shinagawa-ku (JP)

(21) Appl. No.: 13/634,889

(22) PCT Filed: Mar. 14, 2011
(86) PCT No.: PCT/JP2011/001460

§ 371 Date: Sep. 14, 2012

(30) Foreign Application Priority Data
Mar. 15, 2010 (JP) 2010-057530
Mar. 15, 2010 (JP) 2010-057531

(51) Int. Cl. C09D 167/00; C08K 5/13; H01L 23/29

(52) U.S. Cl. 257/789; 523/400; 523/456; 257/E23.117

(57) ABSTRACT

Disclosed is a resin composition for semiconductor encapsulation, containing an epoxy resin (A), a curing agent (B), and an inorganic filler material (C), the epoxy resin (A) including an epoxy resin (A-1) represented by formula (1), and the epoxy resin (A-1) containing a component represented by the formula (1) in which n≧1, and a component (a1) represented by the formula (1) in which n=0 (wherein in the formula (1), R1 represents a hydrocarbon group having 1 to 6 carbon atoms; R2 represents a hydrocarbon group having 1 to 6 carbon atoms, or an aromatic hydrocarbon group having 6 to 14 carbon atoms, while R1s and R2s may be respectively identical with or different from each other; a represents an integer from 0 to 4; b represents an integer from 0 to 4; and n represents an integer of 0 or larger).

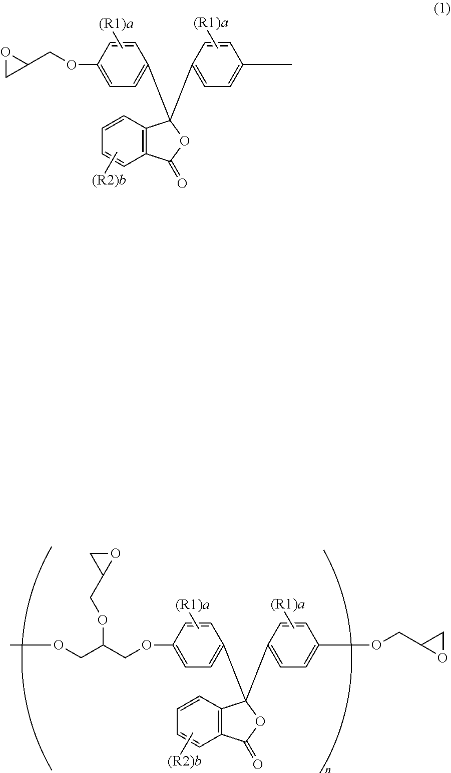

### TECHNICAL FIELD

The present invention relates to a resin composition for encapsulating semiconductor, and a semiconductor device using the same.

### BACKGROUND ART

Semiconductor devices are subjected to encapsulation for the purposes of protection of semiconductor elements, securing of electrical resistance, facilitation of handling, and the like. In regard to the encapsulation of semiconductor elements, encapsulation by transfer molding of an epoxy resin composition is part of the mainstream from the viewpoints of excellent productivity, cost, reliability and the like. In order to cope with the demand of the market to bring miniaturization, weight reduction, and performance enhancement of electronic equipment, not only high integration of semiconductor elements and miniaturization and compactification of semiconductor devices have been achieved, but also new bonding technologies such as surface mounting have been developed and put to practical use. Such technical trend has been spread even to the resin compositions for semiconductor encapsulation, and the level and diversity of the demanded performances are increasing every year.

For example, in regard to the solder used in surface mounting, the conversion to lead-free solder is in progress against the background of environmental problems. The melting point of lead-free solder is higher than the melting point of conventional lead/tin solder, and the reflow mounting temperature is rising from the conventional temperature of 220° C. to 240° C., to the temperature of 240° C. to 260° C. For this reason, resin cracking or detachment may occur in semiconductor devices, or the resistance to solder may be insufficient, at the time of mounting.

Furthermore, in the conventional resin compositions for encapsulation, bromine-containing epoxy resins and antimony oxide have been used as flame retardants for the purpose of imparting flame retardancy. However, the recent tendency to abolish these compounds from the viewpoints of environmental protection and safety enhancement is increasing.

In addition, electronic instruments that are assumed to be used outdoors, such as automobiles and mobile telephones, have been popularized in recent years, and in these applications, operation reliability in an environment harsher than conventional personal computers or electric appliances is required. Particularly in the application in vehicles, high temperature storage characteristics are requested as one of essential requirements, and semiconductors used for this application are required to be capable of maintaining the operation and functions at a high temperature of 150° C. to 180° C.

As related art technologies, there have been suggested a technique of increasing the high temperature storage characteristics and the resistance to solder by using a semiconductor resin composition containing an epoxy resin having a naphthalene skeleton or a phenolic resin curing agent having a naphthalene skeleton (see, for example, Patent Documents 1 and 2), and a technique of increasing the high temperature storage characteristics and flame resistance by incorporating a phosphoric acid-containing compound (see, for example, Patent Documents 3 and 4). However, these techniques may not provide a sufficient balance among continuous moldability, resistance to adherence, flame resistance, and resistance to solder. As described above, with regard to the miniaturization and spread of electronic equipment for vehicles, there is a demand for a resin composition for encapsulation which satisfies continuous moldability, flame resistance, resistance to solder, and high temperature storage characteristics in a well-balanced manner.

### RELATED DOCUMENT

### Patent Document

Patent Document 1: Japanese Patent Application Laid-Open (JP-A) No. 2007-031691

Patent Document 2: JP-A No. 06-216280

Patent Document 3: JP-A No. 2006-161055

Patent Document 4: JP-A No. 2006-176792

### DISCLOSURE OF THE INVENTION

An object of the present invention is to provide a resin composition for encapsulation in which an excellent balance is achieved among continuous moldability, resistance to adherence, flame resistance, resistance to solder and high temperature storage characteristics, at a higher level compared to conventional cases, by using an epoxy resin having a special structure, and to provide a semiconductor device having excellent reliability, which uses the resin composition for encapsulation.

According to the present invention, there is provided a resin composition for semiconductor encapsulation containing an epoxy resin (A), a curing agent (B), and an inorganic filler material (C), the epoxy resin (A) including an epoxy resin (A-1) represented by formula (1):

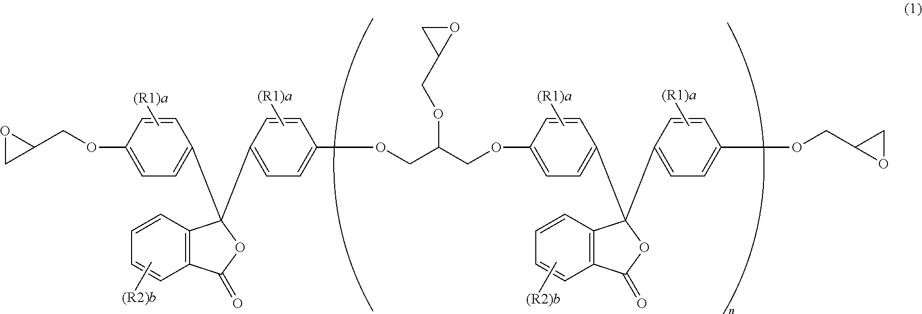

wherein in the formula (1), R1 represents a hydrocarbon group having 1 to 6 carbon atoms; R2 represents a hydrocarbon group having 1 to 6 carbon atoms, or an aromatic hydrocarbon group having 6 to 14 carbon atoms, while R1s and R2s may be respectively identical with or different from each other; a represents an integer from 0 to 4; b represents an integer from 0 to 4; and n represents an integer of 0 or larger, wherein the epoxy resin (A-1) contains a component represented by the formula (1) in which n≧1, and a component (a1) represented by the formula (1) in which n=0.

According to an embodiment of the present invention, in the resin composition for semiconductor encapsulation, a peak intensity measured by FD-MS of the component (a1) is equal to or greater than 50% and equal to or less than 90% with respect to all the peaks of the epoxy resin (A-1), and a peak intensity of the component (a2) in which n=1 in the formula (1) is equal to or greater than 10% and equal to or less than 50% with respect to all the peaks of the epoxy resin (A-1).

According to another embodiment of the present invention, in the resin composition for semiconductor encapsulation, the ratio P₂/P₁ of the peak intensity of the component (a2) P₂, to the peak intensity of the component (a1) P₁, as measured by FD-MS is equal to or greater than 0.1 and equal to or less than 1.0.

According to another embodiment of the present invention, in the resin composition for semiconductor encapsulation, a peak area of the component (a1) relative to the total peak area of the epoxy resin (A-1) obtained by gel permeation chromatography is equal to or greater than 70% by area and equal to or less than 95% by area.

According to another embodiment of the present invention, in the resin composition for semiconductor encapsulation, a ICI viscosity at 150° C. of the epoxy resin (A-1) is equal to or higher than 0.1 dPa·sec and equal to or lower than 3.0 dPa·sec.

According to another embodiment of the present invention, in the resin composition for semiconductor encapsulation, a softening point at 150° C. of the epoxy resin (A-1) is equal to or higher than 55° C. and equal to or lower than 90° C.

According to another embodiment of the present invention, in the resin composition for semiconductor encapsulation, an epoxy equivalent of the epoxy resin (A-1) is equal to or greater than 210 g/eq and equal to or less than 250 g/eq.

According to another embodiment of the present invention, in the resin composition for semiconductor encapsulation, the curing agent (B) is a phenolic resin-based curing agent.

According to another embodiment of the present invention, in the resin composition for semiconductor encapsulation, the phenolic resin-based curing agent includes at least one resin selected from a group consisting of a phenolic resin (B-1) having two or more phenolic skeletons, and a naphthol resin (B-2) having a hydroxynaphthalene skeleton or a dihydroxynaphthalene skeleton.

According to another embodiment of the present invention, in the resin composition for semiconductor encapsulation, the phenolic resin-based curing agent includes at least one resin selected from a group consisting of a phenolic resin (b1) represented by formula (2):

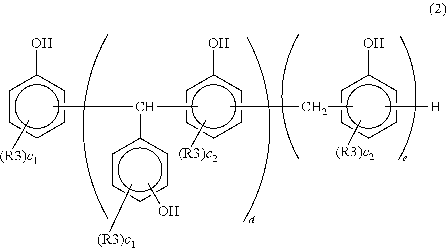

wherein in the formula (2), R3 represents a hydrocarbon group having 1 to 6 carbon atoms or an aromatic hydrocarbon group having 6 to 14 carbon atoms, while R3s may be identical with or different from each other; c1 represents an integer from 0 to 4; c2 represents an integer from 0 to 3, while cis and c2s may be respectively identical with or different from each other; d represents an integer from 1 to 10; e represents an integer from 0 to 10; and a structural unit represented by a repetition number d and the structural unit represented by the repetition number e may be respectively lined up in a row, may be alternately arranged with each other, or may be arranged randomly;

a naphthol resin (b2) represented by formula (3):

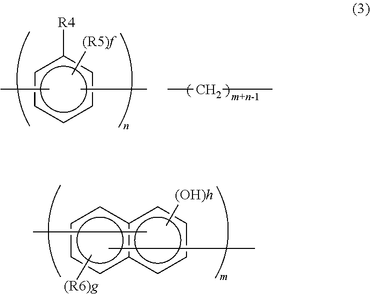

wherein in the formula (3), R4 represents a hydroxyl group or a hydrogen atom; R5 represents a hydrocarbon group having 1 to 6 carbon atoms, or an aromatic hydrocarbon group having 6 to 14 carbon atoms, while R4s and R5s may be respectively identical with or different from each other; R6 represents a hydrocarbon group having 1 to 6 carbon atoms, or an aromatic hydrocarbon group having 6 to 14 carbon atoms, while R6s may be identical with or different from each other; f represents an integer from 0 to 3; g represents an integer from 0 to 5; h represents an integer of 1 or 2; m and n each independently represents an integer from 1 to 10, while m+n≧2; and a structural unit represented by a repetition number m and the structural unit represented by the repetition number n may be respectively lined up in a row, may be alternately arranged with each other, or may be arranged randomly, but —CH₂— is essentially disposed between the respective structures, and

a naphthol resin (b3) represented by formula (4):

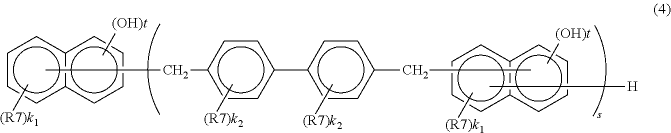

wherein in the formula (4), R7 represents a hydrocarbon group having 1 to 6 carbon atoms, or an aromatic hydrocarbon group having 6 to 14 carbon atoms, while R7s may be identical with or different from each other; k1 represents an integer from 0 to 6; k2 represents an integer from 0 to 4, while k1s and k2s may be respectively identical with or different from each other; s represents an integer from 0 to 10; and t represents an integer of 1 or 2.

According to another embodiment of the present invention, in the resin composition for semiconductor encapsulation, the amount of the at least one resin selected from the group consisting of the phenolic resin (b1), the naphthol resin (b2) and the naphthol resin (b3) is equal to or greater than 50 parts by mass and equal to or less than 100 parts by mass relative to 100 parts by mass of the curing agent (B).

According to another embodiment of the present invention, in the resin composition for semiconductor encapsulation, the amount of the inorganic filler material (C) is equal to or greater than 70% by mass and equal to or less than 93% by mass relative to the total mass of the resin composition for semiconductor encapsulation.

According to another embodiment of the present invention, in the resin composition for semiconductor encapsulation, the amount of the epoxy resin (A-1) is equal to or greater than 50 parts by mass and equal to or less than 100 parts by mass relative to 100 parts by mass of the epoxy resin (A).

According to an embodiment of the present invention, the resin composition for semiconductor encapsulation further contains a curing accelerator (D).

According to another embodiment of the present invention, in the resin composition for semiconductor encapsulation, the curing accelerator (D) includes at least one curing accelerator selected from a group consisting of a tetrasubstituted phosphonium compound, a phosphobetaine compound, an adduct of a phosphine compound and a quinone compound, and an adduct of a phosphonium compound and a silane compound.

According to an embodiment of the present invention, the resin composition for semiconductor encapsulation further contains a compound (E) in which two or more adjacent carbon atoms that constitute an aromatic ring are each bonded to a hydroxyl group.

According to an embodiment of the present invention, the resin composition for semiconductor encapsulation further contains a coupling agent (F).

According to an embodiment of the present invention, the resin composition for semiconductor encapsulation further contains an inorganic flame retardant (G).

According to the present invention, there is provided a semiconductor device including a semiconductor element that is encapsulated with the resin composition for semiconductor encapsulation described above.

According to the present invention, a resin composition for encapsulation which exhibits flame resistance without using a halogen compound and an antimony compound, and may achieve an excellent balance among continuous moldability, resistance to adherence, resistance to solder, and high temperature storage characteristics at a level higher than the conventional resin compositions, and a semiconductor device having excellent reliability, which uses the resin composition for encapsulation, may be obtained.

### BRIEF DESCRIPTION OF THE DRAWINGS

FIG. 1 is a diagram illustrating a cross-sectional structure of an example of a semiconductor device using a resin composition for semiconductor encapsulation according to the present invention.

FIG. 2 is a diagram illustrating a cross-sectional structure of an example of a single-side encapsulation type semiconductor device using the resin composition for semiconductor encapsulation according to the present invention.

FIG. 3 shows an FD-MS of the epoxy resin 1 used in the Examples.

FIG. 4 shows an FD-MS of the epoxy resin 2 used in the Examples.

FIG. 5 shows an FD-MS of the epoxy resin 3 used in the Comparative Examples.

FIG. 6 shows a GPC chart of the epoxy resin 4 used in the Examples.

### DESCRIPTION OF EMBODIMENTS

Suitable embodiments of the resin composition for semiconductor encapsulation and the semiconductor device according to the present invention will be described in detail, with reference to the attached drawings. Meanwhile, in the descriptions of the drawings, identical elements will be assigned with identical symbols, and any overlapping explanations will not be repeated.

The resin composition for semiconductor encapsulation of the present invention contains an epoxy resin (A), a curing agent (B), and an inorganic filler material (C), and the epoxy resin (A) includes an epoxy resin (A-1) represented by formula (1):

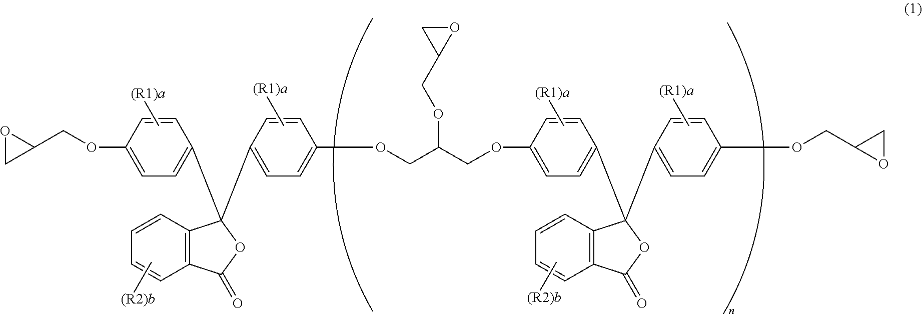

wherein in the formula (1), R1 represents a hydrocarbon group having 1 to 6 carbon atoms; R2 represents a hydrocarbon group having 1 to 6 carbon atoms, or an aromatic hydrocarbon group having 6 to 14 carbon atoms, while R1s and R2s may be respectively identical with or different from each other; a represents an integer from 0 to 4; b represents an integer from 0 to 4; and n represents an integer of 0 or larger. According to the present invention, the epoxy resin (A-1) contains a component represented by the formula (1) in which n≧1, and a component (a1) represented by the formula (1) in which n=0. Furthermore, the semiconductor device of the present invention includes a semiconductor element encapsulated with a cured product of the resin composition for semiconductor encapsulation described above. Hereinafter, the present invention will be described in detail.

First, the resin composition for semiconductor encapsulation of the present invention will be described. In the resin composition for semiconductor encapsulation of the present invention, a phenolphthalein type epoxy resin (A-1) represented by formula (1) (hereinafter, may be referred to as “epoxy resin (A-1)”) is used as the epoxy resin (A).

The epoxy resin (A-1) has a basic skeleton in which a phenol nucleus is directly bonded to a phthalic anhydride skeleton. Accordingly, the rotational motion of the phenol nucleus is restricted, and thus, toughness and heat resistance of the resin composition thus obtainable are enhanced. Furthermore, since the phthalic anhydride skeleton is bulky and has an aromatic structure, the elastic modulus in a high temperature range of the resin composition thus obtainable is decreased, and a foam layer is quickly formed in a combustion test, so that more satisfactory flame resistance is obtained. Such a feature originating from the phthalic anhydride skeleton structure also contributes to an enhancement of the resistance to solder of the resin composition thus obtainable. Particularly, since the epoxy resin (A-1) contains a component having a degree of polymerization of n≧1, which is a polyfunctional component, the resistance to solder is markedly enhanced. This is believed to be because, since the epoxy resin contains (n+1) lactone structures having high polarity in one molecule, the epoxy resin exhibits a chelating interaction with a metal surface, and since the epoxy resin contains (n+2) epoxy groups, the crosslinking density of the metal interface is increased, and consequently, the adhesiveness to metal is increased. Furthermore, the fact that the hydroxy group of the linker is substituted by an epoxy group, and the resin becomes less absorptive as compared with conventional bisphenol type epoxy resins, may also be considered as one of the reasons. Furthermore, in the conventional bisphenol type epoxy resins, as the degree of polymerization increases, the viscosity and the softening point increase along therewith. However, in the case of the epoxy resin (A-1), when the hydroxy group of the linker is substituted by an epoxy group, the viscosity is relatively decreased, and therefore, the epoxy resin has a feature that the flow characteristics of the resin composition are not easily impaired. Furthermore, the epoxy resin (A-1) contains a component (a1) represented by the formula (1) in which n=0. The component (a1) contains a phthalic anhydride skeleton, and has a structure in which a phenol nucleus is bonded to the phthalic anhydride skeleton. The phenol nucleus is strongly bonded to the phthalic anhydride skeleton, and the phenol nucleus is almost incapable of free rotation. When the epoxy resin contains the component (a1) having such a structure, the water absorption rate of the resin composition may be reduced, and toughness and heat resistance may be increased. Furthermore, since the component (a2) represented by the formula (1) in which n=1, has two epoxy groups in the molecule, the elastic modulus at the reflow temperature (240° C. to 260° C.) may be decreased. Due to the polar structures such as a carbonyl structure and an ether structure in the molecule, the adhesiveness to metal surfaces is enhanced, the resin composition has a low water absorption rate and a low elastic modulus on heating as described above, and also, the resistance to solder of the semiconductor encapsulation package is further enhanced. Furthermore, when the elastic modulus in a high temperature range is decreased, a foam layer may be formed quickly in a combustion test, and more satisfactory flame resistance is obtained.

The value of n in the formula (1) may be determined by Field Desorption Mass Spectrometry (FD-MS). For the various peaks detected by an FD-MS analysis measured in a detection mass (m/z) range of 50 to 2,000, the molecular weight and the value of the repetition number n may be obtained at the detection mass (m/z), and each of the n components may be identified by combining various peaks in a GPC analysis. Furthermore, from the intensity ratios of the various peaks, the content ratios (mass ratios) of various components may be determined.

The epoxy resin (A-1) of the present invention contains a component represented by the formula (1) in which n≧1, and a component represented by the formula (1) in which n=0. Preferably, the epoxy resin (A-1) contains a component (a2) represented by the formula (1) in which n=1. In regard to the content proportions of these components in the epoxy resin (A-1), the content proportions may be calculated from the proportions of the peak intensities of FD-MS. The peak intensity of the n=0 component (a1) measured by FD-MS is preferably equal to or greater than 50% and equal to or less than 90%, and more preferably equal to or greater than 55% and equal to or less than 80%, relative to all the detected peaks of the epoxy resin (A-1). The peak intensity of the n=1 component (a2) of the formula (1) is preferably equal to or greater than 10% and equal to or less than 50%, and more preferably equal to or greater than 15% and equal to or less than 45%, relative to all the detected peaks of the epoxy resin (A-1). When the lower limit of the content proportion of the n=1 component (a2) is equal to or greater than the range described above, curability of the resin composition is satisfactory, and continuous moldability and resistance to adherence are satisfactory. When the upper limit of the content proportion of the n=1 component (a2) is equal to or less than the range described above, fluidity of the resin composition is satisfactory. Furthermore, the epoxy resin (A-1) is desirably a resin containing a structure having a degree of polymerization of n≧1, which is a polyfunctional component, and may contain a component in which the glycidyl ether in the structure of the n repeating units in the formula (1) is in the form of the hydroxyl group before being glycidylated.

The ratio P₂/P₁ of the peak intensity P₂ of the component (a2) with respect to the peak intensity P₁ of the component (a1) measured by FD-MS is preferably equal to or greater than 0.1 and equal to or less than 1.0, and more preferably equal to or greater than 0.3 and equal to or less than 0.8.

The content proportion of the component (a1) in the epoxy resin (A-1) is preferably 70% by area or more, and more preferably 80% by area or more, relative to the total peak area of the epoxy resin (A-1) in a gel permeation chromatographic (GPC) analysis. When the lower limit of the content proportion of the component (a1) is in the range described above, fluidity of the resin composition is satisfactory. Furthermore, the upper limit of the content proportion of the component (a1) is preferably 95% by area or less, and more preferably 90% by area or less, as determined by a gel permeation chromatographic (GPC) analysis. When the upper limit of the content proportion of the monomer component is in the range described above, the balance between the flow characteristics and curability of the resin composition is satisfactory, and continuous moldability is satisfactory.

The viscosity of the epoxy resin (A-1) is preferably equal to or higher than 0.1 dPa·sec and equal to or lower than 3.0 dPa·sec, more preferably equal to or higher than 0.2 dPa·sec and equal to or lower than 2.0 dPa·sec, and particularly preferably equal to or higher than 0.3 dPa·sec and equal to or lower than 1.5 dPa·sec, in an ICI viscosity analysis at 150° C. When the lower limit of the ICI viscosity is in the range described above, curability and flame resistance of the resin composition are satisfactory. On the other hand, when the upper limit is in the range described above, fluidity of the resin composition is satisfactory. Meanwhile, the ICI viscosity may be measured by using an ICI cone-plate viscometer manufactured by MST Engineering, Ltd.

The softening point at 150° C. of the epoxy resin (A-1) is preferably equal to or higher than 55° C. and equal to or lower than 90° C., and more preferably equal to or higher than 65° C. and equal to or lower than 80° C. When the lower limit of the softening point is equal to or greater than the range described above, the resistance to adherence of the resin composition is satisfactory. On the other hand, when the upper limit is equal to or less than the range described above, fluidity of the resin composition is satisfactory.

The epoxy equivalent of the epoxy resin (A-1) is preferably equal to or greater than 210 g/eq and equal to or less than 250 g/eq, and more preferably equal to or greater than 225 g/eq and equal to or less than 240 g/eq. When the epoxy equivalent is in the range described above, fluidity, curability and flame resistance of the resin composition are satisfactory.

An example of the method for synthesizing the epoxy resin (A-1) will be described below. The epoxy resin (A-1) is obtained through a two-stage glycidylation reaction. As a first stage, a mixture containing a phenolphthalein compound, an epihalohydrin compound, and optionally an organic solvent is heated and stirred at 60° C. to 100° C. to carry out an etherification reaction between the phenolphthalein compound and the epihalohydrin compound. Subsequently, glycidylation is carried out by sequentially or continuously adding an alkali metal hydroxide under the temperature conditions of 50° C. to 100° C., and in order to further carry out the reaction sufficiently, the reaction is carried out at 50° C. to 100° C. Here, the molecular weight of an intermediate of the epoxy resin (A-1) of the target synthesis product may be controlled by changing the ratio of the phenolphthalein compound and the epihalohydrin compound. For example, when the glycidylation reaction is carried out using the epihalohydrin compound in an amount of 1 to 3 times the weight of the phenolphthalein compound, an intermediate product of the epoxy resin (A-1) containing the n≧1 component may be synthesized. On the other hand, when the glycidylation reaction is carried out using epihalohydrin in an amount of 3 times or more the weight of the phenolphthalein compound, an epoxy resin (A-1) having a very high proportion of the n=0 component (monomer) may be synthesized. As a second stage, when the product obtained in the first stage and an epihalohydrin compound are allowed to react in the presence of a quaternary ammonium salt and an alkali metal hydroxide under the temperature conditions of 50° C. to 100° C., glycidylation of the alcoholic hydroxyl group of the intermediate product may be carried out. Subsequently, unreacted epihalohydrin is collected by distillation, an organic solvent such as toluene or methyl isobutyl ketone (MIBK) is added to the reaction product, and the reaction product is subjected to the processes of water washing-dehydration-filtration-solvent removal. Thus, an intended epoxy resin may be obtained. Furthermore, for the purpose of reducing of the amount of impurity chlorine or the like, a solvent such as dioxane or dimethyl sulfoxide (DMSO) may be used in combination during the reaction.

The phenolphthalein compound that serves as a raw material of the epoxy resin (A-1) is not particularly limited as long as the phenolphthalein compound has a phthalic anhydride skeleton and has a structure in which two phenols are bonded to a carbonyl group on a single side. Examples of phenolphthalein compound which satisfies this condition include phenolphthalein, cresolphthalein, dimethoxyphenolphthalein, dichlorophenolphthalein, and α-naphtholphthalein. From the viewpoint of being industrially easily available, the use of phenolphthalein is particularly preferred. These phenolphthalein compounds may be used singly or as mixtures of two or more kinds.

In the reaction of obtaining the epoxy resin (A-1), epichlorohydrin, epibromohydrin or the like may be used as the epihalohydrin, and epichlorohydrin that is industrially easily available is preferred. The amount of use of epihalohydrin is preferably equal to or more than 1.0 mole and equal to or less than 8.0 moles, and more preferably equal to or more than 2.0 moles and equal to or less than 5.0 moles, relative to 1 mole of the hydroxyl groups of the phenolphthalein compound in the first stage reaction. If the amount of use is less than the range described above, the reaction proceeds incompletely, and there is a risk that the yield may deteriorate. On the other hand, if the amount of use is greater than the range described above, the cost increases, and there is a risk that the amount of chlorine included in the product may increase. Furthermore, in the second stage reaction, the amount of use is preferably equal to or more than 0.5 moles and equal to or less than 5.0 moles, and more preferably equal to or more than 1.0 mole and equal to or less than 3.0 moles, relative to 1 mole of the alcoholic hydroxyl group of the product of the first stage reaction. If the amount of use is less than the lower limit described above, the reaction proceeds incompletely, and epoxidation of alcoholic hydroxyl groups is made difficult. On the other hand, if the amount of use is larger than the upper limit described above, the cost increases, and there is a risk that the amount of chlorine included in the product may increase.

In the second stage reaction for obtaining the epoxy resin (A-1), tetramethylammonium chloride, tetramethylammonium bromide, or the like may be used as the quaternary ammonium salt. The amount of use of the quaternary ammonium salt is preferably equal to or more than 0.01 moles and equal to or less than 0.50 moles, and more preferably equal to or more than 0.03 moles and equal to or less than 0.20 moles, relative to 1 mole of the alcoholic hydroxyl groups of the product of the first stage reaction.

Sodium hydroxide, potassium hydroxide or the like may be used as the alkali metal hydroxide, but sodium hydroxide is preferred. The amount of use of the alkali metal hydroxide is preferably equal to or more than 1-fold equivalent and equal to or less than 10-fold equivalents, and more preferably equal to or more than 1-fold equivalent and equal to or less than 2-fold equivalents, relative to 1 equivalent of the hydroxyl groups to be glycidylated. The alkali metal hydroxide may be in a solid form or may be in an aqueous solution form.

The resin composition for semiconductor encapsulation of the present invention may use another epoxy resin in combination, to the extent that the effect of the epoxy resin (A-1) is not impaired. Examples of the epoxy resin that may be used in combination include novolac type epoxy resins such as a phenol-novolac type epoxy resin, a cresol-novolac type epoxy resin, and a triphenolmethane type epoxy resin; aralkyl type epoxy resins such as a phenol-aralkyl type epoxy resin having a phenylene skeleton, and a phenol-aralkyl type epoxy resin having a biphenylene skeleton; naphthalene type epoxy resins such as a naphthol-aralkyl type epoxy resin having a phenylene skeleton, a naphthol-aralkyl type epoxy resin having a biphenylene skeleton, and a dihydroxynaphthalene type epoxy resin; triazine nucleus-containing epoxy resins such as triglycidyl isocyanurate, and monoallyl diglycidyl isocyanurate; and bridged cyclic hydrocarbon compound-modified phenol type epoxy resins such as a dicyclopentadiene-modified phenol type epoxy resin. In consideration of moisture resistance reliability as an epoxy resin composition for semiconductor encapsulation, an epoxy resin containing ionic impurities such as Na⁺ ion and Cl⁻ ion at the minimum is preferred, and from the viewpoint of curability, the epoxy equivalent is preferably equal to or greater than 100 g/eq and equal to or less than 500 g/eq. These may be used singly, or two or more kinds may be used in combination.

In the case of using such another epoxy resin in combination, the mixing proportion of the epoxy resin (A-1) is preferably equal to or greater than 50 parts by mass and equal to or less than 100 parts by mass, more preferably equal to or greater than 60 parts by mass and equal to or less than 100 parts by mass, and particularly preferably equal to or greater than 70 parts by mass and equal to or less than 100 parts by mass, relative to 100 parts by mass of the epoxy resin (A). When the lower limit of the mixing proportion is equal to or greater than the range described above, continuous moldability, resistance to adherence, flame resistance, resistance to solder, and high temperature storage characteristics may be enhanced, while satisfactory fluidity and curability of the resin composition are maintained.

The lower limit of the total mixing proportion of the epoxy resins is not particularly limited, but the mixing proportion is preferably 2% by mass or more, and more preferably 4% by mass or more, of the whole resin composition. When the lower limit of the mixing proportion is equal to or greater than the range described above, sufficient fluidity may be obtained. Furthermore, the upper limit of the total mixing proportion of the epoxy resins is not particularly limited, but the mixing proportion is preferably 15% by mass or less, and more preferably 13% by mass or less, of the whole resin composition. When the upper limit of the mixing proportion is equal to or less than the range described above, satisfactory resistance to solder may be obtained.

The curing agent (B) used in the resin composition for semiconductor encapsulation of the present invention may be a phenol resin-based curing agent.

The phenol resin-based curing agent of the present invention preferably includes at least one phenol resin-based curing agent selected from the group consisting of a phenol resin (B-1) having a repeating unit structure containing two or more phenol skeletons (hereinafter, may be referred to as “phenol resin (B-1)”), and a naphthol resin (B-2) having a hydroxynaphthalene skeleton or a dihydroxynaphthalene skeleton (hereinafter, may be referred to as “naphthol resin (B-2)”. As a result of a synergistic effect obtained by using the epoxy resin (A-1) and such a phenol resin-based curing agent in combination, the resin composition may achieve an excellent balance among resistance to solder, high temperature storage characteristics, high adhesiveness, and continuous moldability. From the viewpoints of the high temperature storage characteristics and continuous moldability of the resin composition, the phenol resin (B-1) is preferred, and from the viewpoints of the flow characteristics and solder resistance characteristics, the naphthol resin (B-2) is preferred. It is preferable to select the phenol resin-based curing agent in accordance with the characteristics required from the resin composition for semiconductor encapsulation. Furthermore, from the viewpoint of moisture resistance reliability of the resin composition for semiconductor encapsulation thus obtainable and from the viewpoint of curability of the resin composition of the semiconductor, the hydroxyl group equivalent of the phenol resin-based curing agent is preferably equal to or greater than 80 g/eq and equal to or less than 400 g/eq, and more preferably equal to or greater than 90 g/eq and equal to or less than 210 g/eq. When the hydroxyl group equivalent is in this range, the crosslinking density of the cured product of the resin composition is increased, and the cured product may have high heat resistance.

The phenol resin (B-1) is not particularly limited as long as the phenol resin has a repeating unit structure containing two benzene rings to which phenolic hydroxyl groups are bonded. However, a product obtained by polymerizing a phenol compound and an acetylaldehyde compound as essential raw materials using an acid catalyst is preferred, and from the viewpoints of curability and heat resistance, a phenol resin (b1) represented by formula (2) is more preferred. In regard to the phenol resin (b1) represented by formula (2), a phenol resin in which the average value of d is 1 or larger is particularly preferred because this resin has excellent continuous moldability. Examples of such a compound include, as commercially available products, MEH-7500 manufactured by Meiwa Plastic Industries, Ltd., and HE910-20 manufactured by Air Water, Inc.

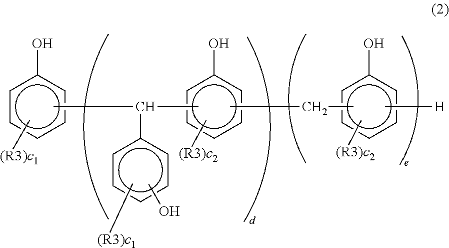

wherein in the formula (2), R3 represents a hydrocarbon group having 1 to 6 carbon atoms, or an aromatic hydrocarbon group having 6 to 14 carbon atoms, while R3s may be identical with or different from each other; c1 represents an integer from 0 to 4; c2 represents an integer from 0 to 3, while c1s and c2s may be respectively identical with or different from each other; d represents an integer from 1 to 10; e represents an integer from 0 to 10; and the structural unit represented by the repetition number d and the structural unit represented by the repetition number e may be respectively lined up in a row, may be alternately arranged with each other, or may be arranged randomly.

The naphthol resin (B-2) is not particularly limited as long as the naphthol resin has a structure having a hydroxynaphthalene skeleton or a dihydroxynaphthalene skeleton. However, from the viewpoint of heat resistance, the naphthol resin is more preferably a naphthol resin (b2) having a structure represented by formula (3) and/or a naphthol resin (b3) represented by formula (4), and particularly preferably a naphthol resin (b3) represented by formula (4). Here, R4 of the naphthol resin (b2) is preferably a hydroxyl group from the viewpoints of curability and continuous moldability, and R4 is preferably a hydrogen atom from the viewpoints of resistance to solder and flame resistance. Furthermore, in regard to the hydroxyl group that is bonded to the naphthalene skeleton, it is preferable that h=1 from the viewpoints of fluidity and resistance to solder, and it is preferable that h=2 from the viewpoints of continuous moldability and curability. Examples of the naphthol resin (b2) include, as commercially available products, KAYAHARD CBN and KAYAHARD NHN manufactured by Nippon Kayaku Co., Ltd., and NC30 manufactured by Gunei Chemical Industry Co., Ltd., in which R4 is a hydroxyl group and h=1; SN-485 and SN-170L manufactured by Tohto Kasei Co., Ltd., in which R4 is a hydrogen atom and h=1; and SN-375 and SN-395 manufactured by Tohto Kasei Co., Ltd., in which R4 is a hydrogen atom and h=2. On the other hand, in regard to the hydroxyl group that is bonded to the naphthalene skeleton of the naphthol resin (b3), it is preferable that t=2 from the viewpoint of high heat resistance. For example, as a synthesis method, when naphthalenediol and 4,4′-bischloromethylbiphenyl are heated to melt in pure water in a nitrogen atmosphere, and the molten product is allowed to react at a high temperature under stirring, a naphthol resin (b3) in which t=2 may be obtained.

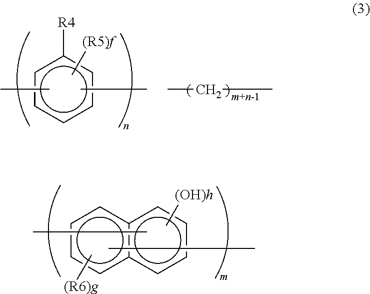

wherein in the formula (3), R4 represents a hydroxyl group or a hydrogen atom; R5 represents a hydrocarbon group having 1 to 6 carbon atoms, or an aromatic hydrocarbon group having 6 to 14 carbon atoms; R4s and R5s may be respectively identical with or different from each other; R6 represents a hydrocarbon group having 1 to 6 carbon atoms, or an aromatic hydrocarbon group having 6 to 14 carbon atoms, while R6s may be identical with or different from each other; f represents an integer from 0 to 3; g represents an integer from 0 to 5; h represents an integer of 1 or 2; m and n each independently represents an integer from 1 to 10, m+n≧2; and the structural unit represented by the repetition number m and the structural unit represented by the repetition number n may be respectively lined up in a row, may be alternately arranged with each other, or may be arranged randomly, but —CH₂— is essentially disposed between the respective structures;

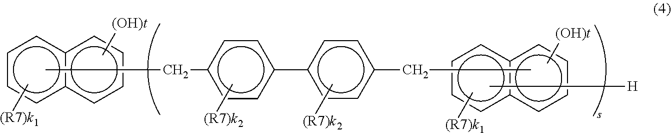

wherein in the formula (4), R7 represents a hydrocarbon group having 1 to 6 carbon atoms, or an aromatic hydrocarbon group having 6 to 14 carbon atoms, while R7s may be identical with or different from each other; k1 represents an integer from 0 to 6; k2 represents an integer from 0 to 4, while k1s and k2s may be respectively identical with or different from each other; s represents an integer from 0 to 10; and t represents an integer of 1 or 2.

The resin composition for semiconductor encapsulation of the present invention may use another curing agent in combination, to the extent that the effect obtainable by using the curing agent (B) is not impaired. The curing agent that may be used in combination is not particularly limited, but examples thereof include a polyaddition type curing agent, a catalyst type curing agent, and a condensed type curing agent.

Examples of the polyaddition type curing agent include polyamine compounds including aliphatic polyamines such as diethylenetriamine, triethylenetetramine, and metaxylenediamine; aromatic polyamines such as diaminodiphenylmethane, m-phenylenediamine, and diaminodiphenylsulfone; dicyanamide, and organic acid dihydrazide; acid anhydrides including alicyclic acid anhydrides such as hexahydrophthalic anhydride and methyltetrahydrophthalic anhydride; and aromatic acid anhydrides such as trimellitic anhydride, pyromellitic anhydride, and benzophenonetetracarboxylic acid; polyphenol compounds such as novolac type phenolic resins, and phenol polymers; polymercaptan compounds such as polysulfide, thioesters, and thioethers; isocyanate compounds such as isocyanate prepolymers and blocked isocyanates; and organic acids such as carboxylic acid-containing polyester resins.

Examples of the catalyst type curing agent include tertiary amine compounds such as benzyldimethylamine and 2,4,6-trisdimethylaminomethylphenol; imidazole compounds such as 2-methylimidazole and 2-ethyl-4-methylimidazole; and Lewis acids such as BF₃ complexes.

Examples of the condensed type curing agent include phenolic resin-based curing agents such as a phenol-aralkyl resin having a phenylene skeleton, and a resol type phenolic resin; urea resins such as a methylol group-containing urea resin; and melamine resins such as a methylol group-containing melamine resin.

Among these, phenolic resin-based curing agents are preferred in view of achieving a balance among flame resistance, moisture resistance, electrical characteristics, curability, storage stability and the like. The phenolic resin-based curing agents include all of monomers, oligomers, and polymers, each having two or more phenolic hydroxyl groups in one molecule, and there are no particular limitations on the molecular weight and molecular structure thereof; however, examples thereof include novolac type resins such as a phenol-novolac resin and a cresol-novolac resin; modified phenolic resins such as a terpene-modified phenolic resin, and a dicyclopentadiene-modified phenolic resin; phenol-aralkyl resins having a phenylene skeleton and/or a biphenylene skeleton; and bisphenol compounds such as bisphenol A and bisphenol F. These may be used singly, or two or more kinds may be used in combination. Among these, from the viewpoint of curability, the hydroxyl group equivalent is preferably equal to or greater than 90 g/eq and equal to or less than 250 g/eq.

In the case of using such another phenolic resin in combination, the mixing proportion of the at least one phenolic resin-based curing agent selected from the group consisting of a phenolic resin (B-1) and a naphthol resin (B-2) is preferably equal to or greater than 50 parts by mass and equal to or less than 100 parts by mass, more preferably equal to or greater than 60 parts by mass and equal to or less than 100 parts by mass, and particularly preferably equal to or greater than 70 parts by mass and equal to or less than 100 parts by mass, relative to 100 parts by mass of the curing agent (B). When the mixing proportion is in the range described above, a synergistic effect induced by the combination with an epoxy resin (A-1) may be obtained.

The lower limit of the total amount of incorporation of the curing agent (B) in the resin composition for semiconductor encapsulation is preferably 0.8% by mass or more, and more preferably 1.5% by mass or more, relative to the total amount of the resin composition for semiconductor encapsulation. When the lower limit is in the range described above, the resin composition thus obtainable has satisfactory fluidity. Furthermore, the upper limit of the total amount of incorporation of the curing agent (B) in the resin composition for semiconductor encapsulation is preferably 10% by mass or less, and more preferably 8% by mass or less, relative to the total amount of the resin composition for semiconductor encapsulation. When the upper limit is in the range described above, the resin composition thus obtainable has satisfactory resistance to solder.

Meanwhile, in regard to the phenolic resin-based curing agent and the epoxy resin in the case of using only a phenolic resin-based curing agent as the curing agent (B), it is preferable to incorporate the phenolic resin-based curing agent and the epoxy resin such that the equivalent ratio (EP)/(OH) between the number of epoxy groups (EP) of the entire epoxy resin and the number of phenolic hydroxyl groups (OH) of the entire phenol resin-based curing agent would be equal to or more than 0.8 and equal to or less than 1.3. When the equivalent ratio is in the range described above, sufficient curing characteristics may be obtained when the resin composition thus obtainable is molded.

In the resin composition for semiconductor encapsulation of the present invention, an inorganic filler material (C) is used. The inorganic filler material (C) to be used in the resin composition for semiconductor encapsulation of the present invention is not particularly limited, but an inorganic filler material that is generally used in the pertinent field may be used. Examples thereof include fused silica, spherical silica, crystalline silica, alumina, silicon nitride, and aluminum nitride. The particle size of the inorganic filler material is preferably equal to or larger than 0.01 μm and equal to or less than 150 μm, from the viewpoint of fillability into the mold cavity.

The content of the inorganic filler material (C) in the resin composition for semiconductor encapsulation is not particularly limited, but the content is preferably 70% by mass or greater, more preferably 73% by mass or greater, and even more preferably 80% by mass or greater, relative to the total mass of the resin composition for semiconductor encapsulation. When the lower limit of the content is equal to or greater than the range described above, the amount of moisture absorption of the cured product of the resin composition for semiconductor encapsulation thus obtainable may be suppressed, or a decrease in the strength may be reduced. Therefore, a cured product having satisfactory resistance to solder cracking may be obtained. Furthermore, the upper limit of the content of the inorganic filler material in the resin composition for semiconductor encapsulation is preferably 93% by mass or less, more preferably 91% by mass or less, and even more preferably 90% by mass or less, relative to the total amount of the resin composition for semiconductor encapsulation. When the upper limit of the content is equal to or less than the range described above, the resin composition thus obtainable has satisfactory fluidity and also has satisfactory moldability. Meanwhile, in the case of using an inorganic flame retardant, such as a metal hydroxide such as aluminum hydroxide or magnesium hydroxide, zinc borate or zinc molybdate, which will be described below, it is preferable to adjust the total amount of these inorganic flame retardants and the inorganic filler material to the range described above.

The resin composition for semiconductor encapsulation of the present invention may further contain a curing accelerator (D). The curing accelerator (D) has an action of accelerating the crosslinking reaction between the epoxy resin and the curing agent, and also may control the balance between the fluidity at the time of curing of the resin composition for semiconductor encapsulation and curability. The curing accelerator may also change the curing characteristics of the cured product.

Specific examples of the curing accelerator (D) include phosphorus atom-containing curing accelerators such as an organic phosphine, a tetrasubstituted phosphonium compound, a phosphobetaine compound, an adduct of a phosphine compound and a quinone compound, and an adduct of a phosphonium compound and a silane compound; and nitrogen atom-containing curing accelerators such as 1,8-diazabicyclo(5,4,0)undecene-7, benzyldimethylamine, and 2-methylimidazole. Among these, phosphorus atom-containing curing accelerators may provide preferable curability. From the viewpoint of the balance between fluidity and curability, at least one compound selected from the group consisting of a tetrasubstituted phosphonium compound, a phosphobetaine compound, an adduct of a phosphine compound and a quinone compound, and an adduct of a phosphonium compound and a silane compound, is more preferred. When the characteristic of fluidity is more emphasized, a tetrasubstituted phosphonium compound is particularly preferred, and when the characteristic of a low elastic modulus on heating of the cured product of the resin composition for semiconductor encapsulation is more emphasized, a phosphobetaine compound, and an adduct of a phosphine compound and a quinone compound are particularly preferred. Furthermore, when the characteristic of latent curability is more emphasized, an adduct of a phosphonium compound and a silane compound are particularly preferred.

Examples of the organic phosphine that may be used in the resin composition for semiconductor encapsulation of the present invention include primary phosphines such as ethylphosphine and phenylphosphine; secondary phosphines such as dimethylphosphine and diphenylphosphine; and tertiary phosphines such as trimethylphosphine, triethylphosphine, tributylphosphine, and triphenylphosphine.

Examples of the tetrasubstituted phosphonium compound that may be used in the resin composition for semiconductor encapsulation of the present invention include compounds represented by formula (5):

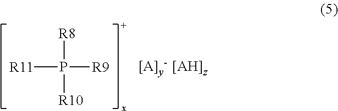

wherein in the formula (5), P represents a phosphorus atom; R8, R9, R10 and R11 each represents an aromatic group or an alkyl group; A represents an anion of an aromatic organic acid having at least one group selected from the group consisting of a hydroxyl group, a carboxyl group and a thiol group in the aromatic ring; AH represents an aromatic organic acid having at least one group selected from the group consisting of a hydroxyl group, a carboxyl group and a thiol group in the aromatic ring; x and y each represents an integer from 1 to 3; z represents an integer from 0 to 3; and x=y.

A compound represented by the formula (5) may be obtained, for example, in a manner such as follows, but the method is not intended to be limited to this. First, a tetrasubstituted phosphonium halide, an aromatic organic acid, and a base are mixed in an organic solvent, the mixture is uniformly mixed, and an aromatic organic acid anion is generated in the solution system. Subsequently, a compound represented by the formula (5) may be precipitated by adding water. In the compound represented by the formula (5), a compound in which R8, R9, R10 and R11 that are bonded to the phosphorus atom are phenyl groups; AH is a compound having a hydroxyl group on an aromatic ring, that is, a phenol compound; and A is an anion of the phenol compound, is preferred.

Examples of the phosphobetaine compound that may be used in the resin composition for semiconductor encapsulation of the present invention include compounds represented by formula (6):

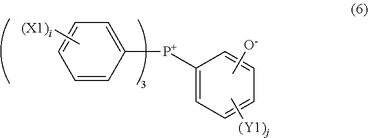

wherein in the formula (6), X1 represents an alkyl group having 1 to 3 carbon atoms; Y1 represents a hydroxyl group; i represents an integer from 0 to 5; and j represents an integer from 0 to 4.

A compound represented by the formula (6) may be obtained, for example, in a manner such as follows. The compound is obtained through a process of, first, bringing a triaromatic-substituted phosphine as a tertiary phosphine, and a diazonium salt into contact, and substituting the triaromatic-substituted phosphine and the diazonium group carried by the diazonium salt. However, the method is not intended to be limited to this.

Examples of the adduct of a phosphine compound and a quinone compound that may be used in the resin composition for semiconductor encapsulation of the present invention include compounds represented by formula (7):

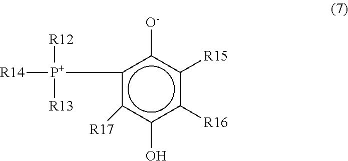

wherein in the formula (7), P represents a phosphorus atom; R12, R13 and R14 each represents an alkyl group having 1 to 12 carbon atoms, or an aryl group having 6 to 12 carbon atoms; R12, R13 and R14 may be respectively identical with or different from each other; R15, R16 and R17 each represents a hydrogen atom or a hydrocarbon group having 1 to 12 carbon atoms; R15, R16 and R17 may be respectively identical with or different from each other; and R15 and R16 may be joined to form a cyclic structure.

As the phosphine compound that is used in the adduct of a phosphine compound and a quinone compound, for example, phosphine compounds having an unsubstituted aromatic ring or having an aromatic ring having a substituent such as an alkyl group or an alkoxy group, such as triphenylphosphine, tris(alkylphenyl)phosphine, tris(alkoxyphenyl)phosphine, trinaphthylphosphine and tris(benzyl)phosphine, are preferred, and the substituent such as an alkyl group or an alkoxy group may be a substituent having 1 to 6 carbon atoms. From the viewpoint of easy availability, triphenylphosphine is preferred.

Furthermore, examples of the quinone compound that is used in the adduct of a phosphine compound and a quinone compound include o-benzoquinone, p-benzoquinone, and anthraquinones, and among these, p-benzoquinone is preferred from the viewpoint of storage stability.

As the method for producing an adduct of a phosphine compound and a quinone compound, an adduct may be obtained by bringing an organic tertiary phosphine and a benzoquinone compound into contact in a solvent which may dissolve both the compounds, and mixing the compounds. As the solvent, a ketone in which the adduct is less soluble, such as acetone or methyl ethyl ketone, is preferred. However, the solvent is not intended to be limited to this.

In the compound represented by the formula (7), a compound in which R12, R13 and R14 that are bonded to the phosphorus atom are phenyl groups; and R15, R16 and R17 are hydrogen atoms, that is, a compound obtained by addition of 1,4-benzoquinone and triphenylphosphine, is preferred from the viewpoint that the elastic modulus on heating of the cured product of the resin composition for semiconductor encapsulation may be maintained low.

Examples of the adduct of a phosphonium compound and a silane compound that may be used in the resin composition for semiconductor encapsulation of the present invention include compounds represented by formula (8):

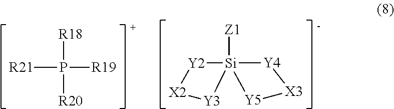

wherein in the formula (8), P represents a phosphorus atom; Si represents a silicon atom; R18, R19, R20 and R21 each independently represent an organic group having an aromatic ring or a heterocyclic ring, or an aliphatic group, while R18, R19, R20 and R21 may be respectively identical with or different from each other; X2 represents an organic group that is bonded to the groups Y2 and Y3; X3 represents an organic group that is bonded to the groups Y4 and Y5; Y2 and Y3 each represents a group that is formed when a proton-donating group releases a proton, while groups Y2 and Y3 in the same molecule are joined with a silicon atom to form a chelate structure; Y4 and Y5 each represents a group that is formed when a proton-donating group releases a proton, while groups Y4 and Y5 in the same molecule are joined with a silicon atom to form a chelate structure; X2 and X3 may be respectively identical with or different from each other; Y2, Y3, Y4 and Y5 may be respectively identical with or different from each other; and Z1 represents an organic group having an aromatic ring or a heterocyclic ring, or an aliphatic group.

In the formula (8), examples of R18, R19, R20 and R21 include a phenyl group, a methylphenyl group, a methoxyphenyl group, a hydroxyphenyl group, a naphthyl group, a hydroxynaphthyl group, a benzyl group, a methyl group, an ethyl group, an n-butyl group, an n-octyl group, and a cyclohexyl group. Among these, an aromatic group having a substituent such as a phenyl group, a methylphenyl group, a methoxyphenyl group, a hydroxyphenyl group, or a hydroxynaphthyl group, or an unsubstituted aromatic group is more preferred.

In the formula (8), X2 represents an organic group that is bonded to Y2 and Y3. Similarly, X3 represents an organic group that is bonded to groups Y4 and Y5. Y2 and Y3 are groups formed when proton-donating groups release protons, and the groups Y2 and Y3 in the same molecule are joined with a silicon atom to form a chelate structure. Similarly, Y4 and Y5 are groups formed when proton-donating groups release protons, and the groups Y4 and Y5 in the same molecule are joined with a silicon atom to form a chelate structure. The groups X2 and X3 may be respectively identical with or different from each other, and the groups Y2, Y3, Y4, and Y5 may be respectively identical with or different from each other. Such a group represented by —Y2-X2-Y3- and —Y4-X3-Y5- in the formula (8) is composed of a group formed when a proton donor release two protons, and examples of the proton donor include catechol, pyrogallol, 1,2-dihydroxynaphthalene, 2,3-dihydroxynaphthalene, 2,2′-biphenol, 1,1′-bi-2-naphthol, salicylic acid, 1-hydroxy-2-naphthoic acid, 3-hydroxy-2-naphthoic acid, chloranilic acid, tannic acid, 2-hydroxybenzyl alcohol, 1,2-cyclohexanediol, 1,2-proapnediol, and glycerin. Among these, catechol, 1,2-dihydroxynaphthalene, and 2,3-dihydroxynaphthalene are more preferred.

Z1 in the formula (8) represents an organic group having an aromatic ring or a heterocyclic ring, or an aliphatic group, and specific examples thereof include aliphatic hydrocarbon groups such as a methyl group, an ethyl group, a propyl group, a butyl group, a hexyl group and an octyl group; aromatic hydrocarbon groups such as a phenyl group, a benzyl group, a naphthyl group, and a biphenyl group; and reactive substituents such as a glycidyloxypropyl group, a mercaptopropyl group, an aminopropyl group, and a vinyl group. Among these, a methyl group, an ethyl group, a phenyl group, a naphthyl group and a biphenyl group are more preferred from the viewpoint that thermal stability of the compound of the formula (8) is enhanced.

As the method for producing an adduct of a phosphonium compound and a silane compound, a silane compound such as phenyltrimethoxysilane and a proton donor such as 2,3-dihydroxynaphthalene are added to a flask containing methanol and were dissolved in methanol. Subsequently, a methanol solution of sodium methoxide is added dropwise thereto under stirring at room temperature. Furthermore, when a solution prepared in advance by dissolving a tetrasubstituted phosphonium halide such as tetraphenylphosphonium bromide in methanol is added dropwise to the mixture under stirring at room temperature, crystals are precipitated out. The precipitated crystals are filtered, washed with water, and dried in vacuum, and thus an adduct of a phosphonium compound and a silane compound may be obtained. However, the production method is not intended to be limited to this.

The mixing proportion of the curing accelerator (D) that may be used in the resin composition for semiconductor encapsulation of the present invention is preferably equal to or greater than 0.1% by mass and equal to or less than 1% by mass of the whole resin composition. When the amount of incorporation of the curing accelerator (D) is in the range described above, sufficient curability and fluidity may be obtained.

The resin composition for semiconductor encapsulation of the present invention may further contain a compound (E) in which two or more adjacent carbon atoms that constitute an aromatic ring are each bonded to a hydroxyl group (hereinafter, also referred to as “compound (E)”). When the compound (E) is used, even when a phosphorus atom-containing curing accelerator which does not have latency is used as the curing accelerator (D) that accelerates the crosslinking reaction between a phenolic resin and an epoxy resin, the reaction during the melt kneading of the resin mixture may be suppressed, and a resin composition for semiconductor encapsulation may be stably obtained. Furthermore, the compound (E) also has an effect of decreasing the melt viscosity of the resin composition for semiconductor encapsulation and enhancing fluidity of the resin composition. As the compound (E), a monocyclic compound represented by formula (9) or a polycyclic compound represented by formula (10) may be used, and such a compound may have a substituent other than a hydroxyl group.

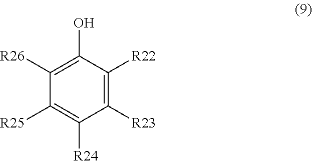

wherein in the formula (9), any one of R22 and R26 represents a hydroxyl group, while the other represents a hydrogen atom, a hydroxyl group, or a substituent other than a hydroxyl group; and R23, R24 and R25 each represents a hydrogen atom, a hydroxyl group, or a substituent other than a hydroxyl group.

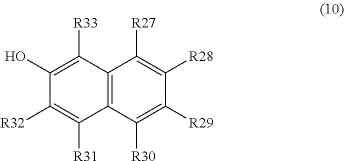

wherein in the formula (10), any one of R32 and R33 represents a hydroxyl group, while the other represents a hydrogen atom, a hydroxyl group, or a substituent other than a hydroxyl group; and R27, R28, R29, R30 and R31 each represents a hydrogen atom, a hydroxyl group, or a substituent other than a hydroxyl group.

Examples of the monocyclic compound represented by the formula (9) include catechol, pyrogallol, gallic acid, gallic acid esters, and derivatives thereof. Furthermore, examples of the polycyclic compound represented by the formula (10) include 1,2-dihydroxynaphthalene, 2,3-dihydroxynaphthalene, and derivatives thereof. Among these, from the viewpoint that it is easy to control fluidity and curability, a compound in which two adjacent carbon atoms that constitute an aromatic ring are each bonded to a hydroxyl group, is preferred. Furthermore, when volatilization during the kneading process is considered, it is more preferable to employ a compound in which the mother nucleus is a naphthalene ring which is less volatile and has high weight stability. In this case, specifically, for example, a compound having a naphthalene ring, such as 1,2-dihydroxynaphthalene, 2,3-dihydroxynaphthalene, or a derivative thereof, may be employed as the compound (E). These compounds (E) may be used singly, or two or more kinds may be used in combination.

The amount of incorporation of the compound (E) is preferably equal to or more than 0.01% by mass and equal to or less than 1% by mass, more preferably equal to or more than 0.03% by mass and equal to or less than 0.8% by mass, and particularly preferably equal to or more than 0.05% by mass and equal to or less than 0.5% by mass, of the total amount of the resin composition for semiconductor encapsulation. When the lower limit of the amount of incorporation of the compound (E) is in the range described above, sufficient effects of decreasing the viscosity of the resin composition for semiconductor encapsulation, and enhancing the fluidity of the resin composition may be obtained. Furthermore, when the upper limit of the amount of incorporation of the compound (E) is in the range described above, the risk of causing a decrease in curability and continuous moldability of the resin composition for semiconductor encapsulation, or causing cracks at the solder reflow temperature, is small.

In the resin composition for semiconductor encapsulation of the present invention, a coupling agent (F) may be further added in order to enhance the adhesiveness between an epoxy resin and an inorganic filler material. There are no particular limitations on the coupling agent, but examples thereof include epoxysilanes, aminosilanes, ureidosilanes, and mercaptosilanes. Any compound which reacts or acts between an epoxy resin and an inorganic filler material, and thereby enhances the interfacial strength between the epoxy resin and the inorganic filler material, is preferred. Furthermore, when used in combination with the compound (E) described above, the coupling agent (F) is capable of increasing the effect of the compound (E) of decreasing the melt viscosity of the resin composition and enhancing fluidity of the resin composition.

Examples of epoxysilanes include γ-glycidoxypropyltriethoxysilane, γ-glycidoxypropyltrimethoxysilane, γ-glycidoxypropylmethyldimethoxysilane, and β-(3,4-epoxycyclohexyl)ethyltrimethoxysilane.

Examples of aminosilanes such as γ-aminopropyltriethoxysilane, γ-aminopropyltrimethoxysilane, N-β-(aminoethyl)-γ-aminopropyltrimethoxysilane, N-β-(aminoethyl)-γ-aminopropylmethyldimethoxysilane, N-phenyl-γ-aminopropyltriethoxysilane, N-phenyl-γ-aminopropyltrimethoxysilane, N-β-(aminoethyl)-γ-aminopropyltriethoxysilane, and N-6-(aminohexyl)-3-aminopropyltrimethoxysilane. An aminosilane which is protected by allowing the primary amino site of the aminosilane to react with a ketone or an aldehyde, may also be used as a latent aminosilane coupling agent.

Examples of ureidosilanes include γ-ureidopropyltriethoxysilane, and hexamethyldisilazane.

Examples of mercaptosilanes include γ-mercaptopropyltrimethoxysilane, 3-mercaptopropylmethyldimethoxysilane, as well as a silane coupling agent which exhibits the same function as a mercaptosilane coupling agent when thermally degraded, such as bis(3-triethoxysilylpropyl)tetrasulfide or bis(3-triethoxysilylpropyl)disulfide. Furthermore, products obtained by hydrolyzing these silane coupling agents in advance may also be incorporated. These silane coupling agents may be used singly, or two or more kinds may be used in combination.

The lower limit of the mixing proportion of the coupling agent (F) that may be used in the resin composition for semiconductor encapsulation of the present invention is preferably 0.01% by mass or greater, more preferably 0.05% by mass or greater, and particularly preferably 0.1% by mass or greater, of the whole resin composition. When the lower limit of the mixing proportion of the coupling agent (F) is in the range described above, there is no decrease in the interfacial strength between the epoxy resin and the inorganic filler material, and satisfactory resistance to solder cracking in the semiconductor device may be obtained. The upper limit of the mixing proportion of the coupling agent (F) is preferably 1.0% by mass or less, more preferably 0.8% by mass or less, and particularly preferably 0.6% by mass or less, of the whole resin composition. When the upper limit of the mixing proportion of the coupling agent (F) is in the range described above, there is no decrease in the interfacial strength between the epoxy resin and the inorganic filler material, and satisfactory resistance to solder cracking in the semiconductor device may be obtained. Furthermore, when the mixing proportion of the coupling agent (F) is in the range described above, there is no increase in the water absorption rate of the cured product of the resin composition, and satisfactory resistance to solder cracking in the semiconductor device may be obtained.

In the resin composition for semiconductor encapsulation of the present invention, an inorganic flame retardant (G) may be further added in order to increase flame resistance. Examples thereof include, but are not particularly limited to, metal hydroxides such as aluminum hydroxide and magnesium hydroxide; zinc borate, and zinc molybdate. These inorganic flame retardants (G) may be used singly, or two or more kinds may be used in combination.

The mixing proportion of the inorganic flame retardant (G) that may be used in the resin composition for semiconductor encapsulation of the present invention is preferably equal to or greater than 0.5% by mass and equal to or less than 6.0% by mass of the whole resin composition. When the mixing proportion of the inorganic flame retardant (G) is in the range described above, an effect of enhancing flame resistance may be obtained, without impairing curability or characteristics.

In the resin composition for semiconductor encapsulation of the present invention, an ion trapping agent (H) may be further added in order to enhance moisture resistance reliability such as HAST (Highly Accelerated temperature and humidity Stress Test). Examples of the ion trapping agent (H) include hydrotalcites, and hydrated oxides of elements selected from magnesium, aluminum, bismuth, titanium, and zirconium. These may be used singly, or two or more kinds may be used in combination. Among these, hydrotalcites are preferred.

The amount of incorporation of the ion trapping agent (H) is not particularly limited, but the amount of incorporation is preferably equal to or greater than 0.05% by mass and equal to or less than 3% by mass, and more preferably equal to or greater than 0.1% by mass and equal to or less than 1% by mass, of the total amount of the resin composition for semiconductor encapsulation. When the amount of incorporation is in the range described above, an effect of exhibiting a sufficient ion supplementing action and enhancing moisture resistance reliability is obtained, and also, the adverse effect on the characteristics of other materials is reduced.

In the resin composition for semiconductor encapsulation of the present invention, additives including colorants such as carbon black, red iron oxide, and titanium oxide; releasing agents, such as natural waxes such as carnauba wax, synthetic waxes such as polyethylene waxes, higher fatty acids and metal salts thereof such as stearic acid and zinc stearate, or paraffin; low stress additives such as silicone oils and silicone rubbers; inorganic ion exchangers such as bismuth oxide hydrate; and inorganic flame retardants such as phosphoric acid esters and phosphazene, may also be appropriately incorporated in addition to the components mentioned above.

The resin composition for semiconductor encapsulation of the present invention is prepared by uniformly mixing the epoxy resin (A), the curing agent (B) and the inorganic filler material (C), as well as other components described above using, for example, a mixer or the like at normal temperature.

Thereafter, if necessary, the mixture is melt kneaded using a kneading machine such as a heated roll, a kneader or an extruder, and subsequently, the kneading product is cooled and pulverized as necessary. Thereby, the dispersity, fluidity and the like may be adjusted to desired values.

Next, the semiconductor device of the present invention will be described. As the method for producing a semiconductor device by using the resin composition for semiconductor encapsulation of the present invention, for example, a method of installing a lead frame or a circuit board on which a semiconductor element has been mounted, in the cavity of a mold, subsequently molding the resin composition for semiconductor encapsulation by a molding method such as transfer molding, compression molding or injection molding, and curing, and thereby encapsulating this semiconductor element, may be mentioned.

Examples of the semiconductor element that is encapsulated include, but are not limited to, integrated circuits, large scale integrations, transistors, thyristors, diodes, and solid state imaging elements.

Examples of the form of semiconductor device thus obtainable include, but are not limited to, dual in-line package (DIP), plastic lead chip carriers (PLCC), quad flat package (QFP), low profile quad flat package (LQFP), small outline package (SOP), small outline J-lead package (SOJ), thin small outline package (TSOP), thin quad flat package (TQFP), tape carrier package (TCP), ball grid array (BGA), and chip size package (CSP).

A semiconductor device in which a semiconductor element is encapsulated with the resin composition for semiconductor encapsulation by a molding method such as transfer molding, is mounted on an electronic instrument or the like either directly or after this resin composition is completely cured over a time period of about 10 minutes to 10 hours at a temperature of about 80° C. to 200° C.

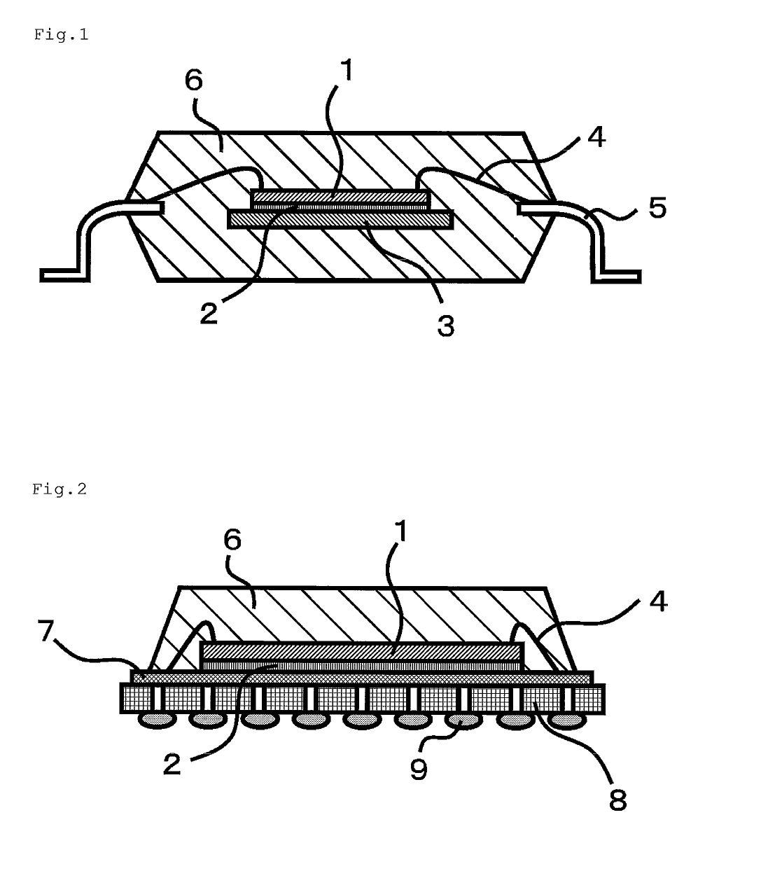

FIG. 1 is a diagram illustrating the cross-sectional structure of a semiconductor device using the resin composition for semiconductor encapsulation according to the present invention. A semiconductor element 1 is fixed onto a die pad 3 by means of a cured product of a die bonding material 2. An electrode pad of the semiconductor element 1 and a lead frame 5 are connected by a gold wire 4. The semiconductor element 1 is encapsulated by a cured product 6 of the resin composition for semiconductor encapsulation of the present invention.

FIG. 2 is a diagram illustrating the cross-sectional structure in an example of a single-side encapsulation type semiconductor device using a resin composition for semiconductor encapsulation according to the present invention. A semiconductor element 1 is fixed onto the solder resist 7 of a laminate in which a layer of a solder resist 7 is formed, on the surface of a substrate 8 by means of a cured product of a die bonding material 2. Furthermore, in order to enable conduction between the semiconductor element and the substrate, the solder resist 7 on the electrode pad has been removed by a development method so that the electrode pad is exposed. Therefore, the semiconductor device of FIG. 2 is designed such that the electrode pad of the semiconductor element 1 and the electrode pad on the substrate 8 are connected by a gold wire 4. When the resin composition for semiconductor encapsulation is molded to form a cured product 6 of the resin composition for semiconductor encapsulation, a semiconductor device in which only one surface side of the substrate 8 where the semiconductor element 1 is mounted is encapsulated, may be obtained. The electrode pad on the substrate 8 is internally bonded to the solder balls 9 on the non-encapsulated surface side of the substrate 8.

### EXAMPLES

Hereinafter, the present invention will be described in detail by way of Examples, but the present invention is not intended to be limited by the descriptions of these Examples. Unless particularly stated otherwise, the amounts of incorporations of various components in the following descriptions are on a mass basis.

In the following Examples 1 to 12 and Comparative Examples 1 to 4, resin compositions containing the components indicated in Tables 1 to 4 in predetermined amounts of incorporation were prepared, and the resin compositions were evaluated in terms of spiral flow, continuous moldability, resistance to adherence, flame resistance, resistance to solder, and high temperature storage characteristics.

As the epoxy resin (A), the following epoxy resins 1 to 3 were used.

Among these, epoxy resins 1 and 2 correspond to the epoxy resin (A-1).

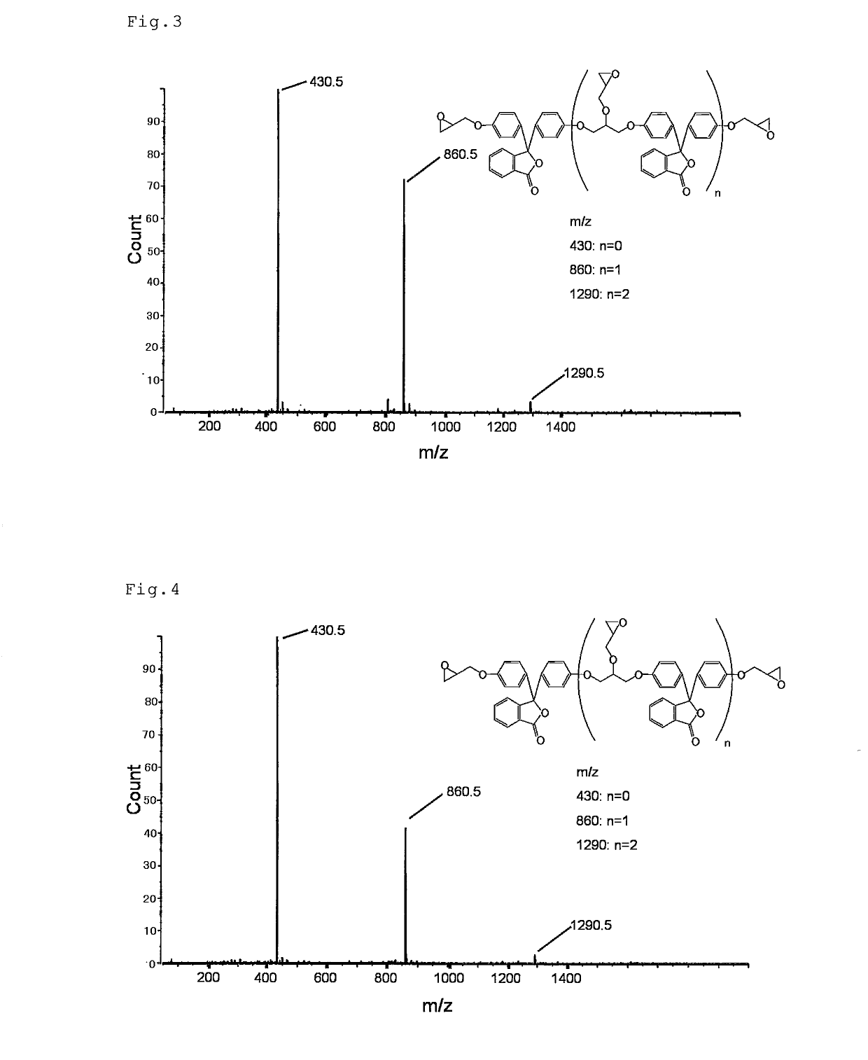

Epoxy resin 1: Synthesis was carried out by a two-stage reaction. As a first stage, in a separable flask equipped with a stirring device, a thermometer, a reflux cooler, and a nitrogen inlet port, 100 parts by mass of phenolphthalein (manufactured by Tokyo Chemical Industry Co., Ltd.) and 150 parts by mass of epichlorohydrin (manufactured by Tokyo Chemical Industry Co., Ltd.) were weighed, and the mixture was dissolved by heating to 90° C. Subsequently, 50 parts by mass of sodium hydroxide (solid fine particulate form, 99% purity reagent) was slowly added thereto over 4 hours, and the resulting mixture was heated to 100° C. and allowed to react for 2 hours. At the time point when the color of the solution turned yellow, the reaction was terminated. After the reaction, an operation (water washing) of adding 150 parts by mass of distilled water, shaking the reaction mixture, and then discarding the aqueous layer was repeatedly carried out until the washing water became neutral. Subsequently, as a second stage reaction, in a separable flask equipped with a stirring device, a thermometer, a reflux cooler, and a nitrogen inlet port, 100 parts by mass of the intermediate obtained in the first stage, 100 parts by mass of epichlorohydrin (manufactured by Tokyo Chemical Industry Co., Ltd.), and 3 parts by mass of tetramethylammonium chloride (manufactured by Wako Pure Chemical Industries, Ltd.) were weighed, and the mixture was dissolved by heating to 90° C. Subsequently, 30 parts by mass of sodium hydroxide (solid fine particulate form, 99% purity reagent) was slowly added thereto over 4 hours, and the resulting mixture was heated to 100° C. and allowed to react for 2 hours. After the reaction, an operation (water washing) of adding 150 parts by mass of distilled water, shaking the mixture, and then discarding the aqueous layer was repeated until the washing water became neutral. Subsequently, epichlorohydrin was distilled off from the oil layer under reduced pressure conditions of 125° C. and 2 mmHg. 250 parts by mass of methyl isobutyl ketone was added to the solid thus obtained to dissolve the solid, and the solution was heated to 70° C. 13 parts by mass of a 30 mass % aqueous solution of sodium hydroxide was added to the reaction mixture over one hour, and the mixture was allowed to react for another one hour. Subsequently, the reaction mixture was left to stand, and the aqueous layer was discarded. An operation of water washing was carried out by adding 150 parts by mass of distilled water to the oil layer, and the same water washing operation was repeatedly carried out until the washing water became neutral. Subsequently, methyl isobutyl ketone was distilled off by heating under reduced pressure, and thus an epoxy resin 1 containing a compound represented by formula (11) (epoxy equivalent: 234 g/eq, softening point: 75° C., ICI viscosity at 150° C.: 1.50 dPa·sec) was obtained. The FD-MS spectrum of the epoxy resin 1 is presented in FIG. 3. The peak intensity fractions of the various components of the epoxy resin 1 obtained from the FD-MS spectrum are presented in Table 1. From these results, it was confirmed that the epoxy resin 1 contained 56.9% of a component represented by formula (11) in which n=0, 41.4% of a component represented by formula (11) in which n=1, and 1.7% of a component represented by formula (11) in which n=2.

Epoxy resin 2: An epoxy resin 2 (epoxy equivalent: 225 g/eq, softening point: 65° C., ICI viscosity at 150° C.: 1.10 dPa·sec) was obtained by the same operation as that used for the epoxy resin 1, except that 100 parts by mass of phenolphthalein (manufactured by Tokyo Chemical Industry Co., Ltd.) and 300 parts by mass of epichlorohydrin (manufactured by Tokyo Chemical Industry Co., Ltd.) were used in the reaction of the first stage. The FD-MS spectrum of epoxy resin 2 is presented in FIG. 4. The peak intensity fractions of the various components of the epoxy resin 2 obtained from the FD-MS spectrum are presented in Table 1. From these results, it was confirmed that the epoxy resin 2 contained 69.7% of a component represented by formula (11) in which n=0, 28.9% of a component represented by formula (11) in which n=1, and 1.4% of a component represented by formula (11) in which n=2.

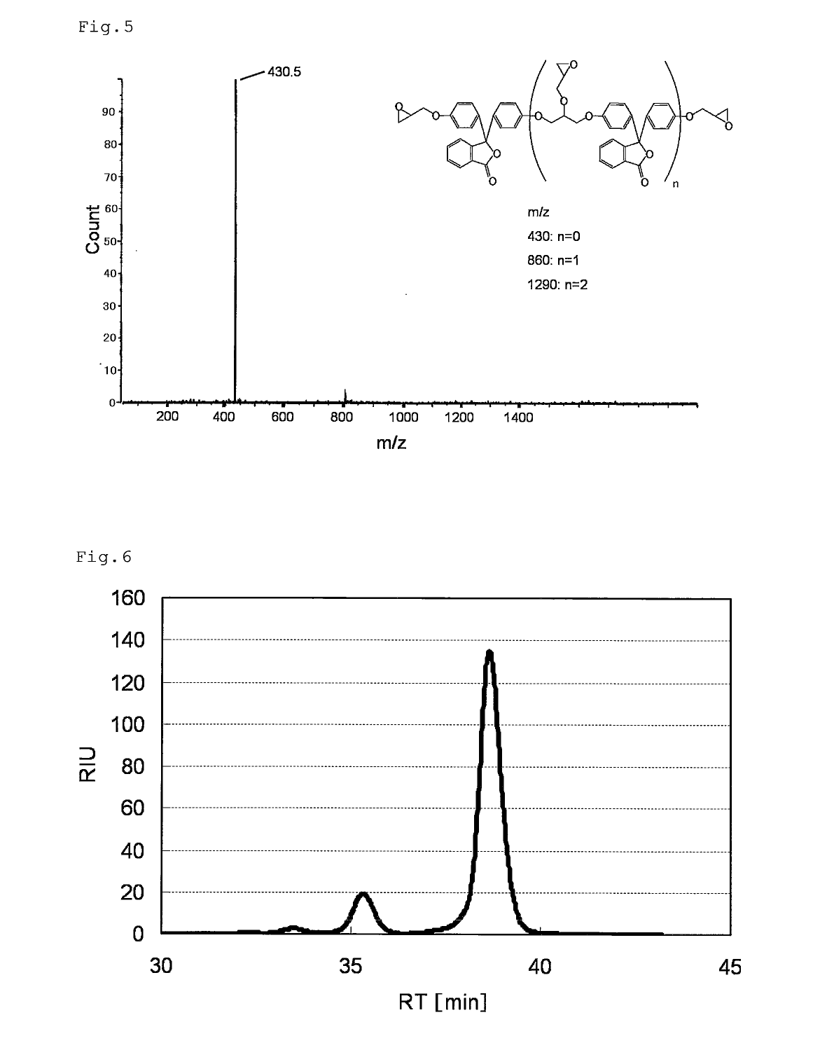

Epoxy resin 3: A 10% sample solution was prepared by adding tetrahydrofuran to the intermediate obtained by performing the first stage reaction and then purifying the product when the epoxy resin 2 described above was synthesized, and the sample solution was subjected to column chromatographic fractionation. As the fractionation column, a column container having an internal diameter of 80 mm×a length of 300 mm and filled with a polystyrene gel (manufactured by Yamazen Corp., particle size: 40 μm, pore size: 60 Å) was used, and a separatory funnel, a column, a refractive index (R1) detector, and a valve for liquid separation and collection were connected in series. The sample solution was supplied from the separatory funnel, and then tetrahydrofuran eluent was supplied. The refractive index (RI) chart was monitored, and an extracting solution coming from the point after about 37 seconds to the point after about 40 seconds was collected. Through this operation, an epoxy resin 3 (epoxy equivalent: 218 g/eq, softening point: 53° C., ICI viscosity at 150° C.: 0.30 dPa·sec) was obtained. The results of FD-MS of the epoxy resin 3 are presented in FIG. 5. From these results, it was confirmed that only a component represented by formula (11) in which n=0 was contained, and the n=1 component and the n=2 component were not confirmed.

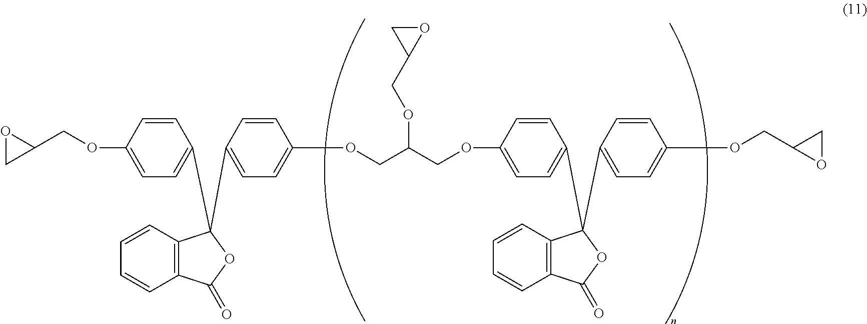

The FD-MS analysis of the epoxy resins 1 to 3 was carried out under the following conditions. 1 g of dimethyl sulfoxide solvent was added to 10 mg of a sample of one of the epoxy resins 1 to 3, and the sample was sufficiently dissolved therein. Subsequently, the solution was applied on the FD emitter and was subjected to an analysis. Measurement was carried out in a detection mass range (m/z) of 50 to 2000 of by using an FD-MS system in which MS-FD15A manufactured by JEOL, Ltd. was connected to the ionization unit, and Model MS-700 double focusing mass spectrometer manufactured by JEOL, Ltd. was connected to the detector.

TABLE 1

| Epoxy resin | Epoxy resin 1 | Epoxy resin 2 | Epoxy resin 3 |
|---|---|---|---|
| Epoxy group equivalent | 234 | 225 | 218 |
| [g/eq] | | | |
| Softening point [° C.] | 75 | 65 | 53 |
| ICI viscosity [dPa · sec] | 1.5 | 1.1 | 0.3 |
| FD-MS measurement value | | | |
| Peak intensity fraction | 56.9 | 69.7 | 100.0 |
| P₁ of n = 0 component [%] | | | |
| Peak intensity fraction | 41.4 | 28.9 | — |
| P₂ of n = 1 component [%] | | | |
| Peak intensity fraction | 1.7 | 1.4 | — |
| of n = 2 component [%] | | | |
| Peak intensity ratio P₂/P₁ | 0.73 | 0.41 | — |

For the phenolic resin as the curing agent (B), the following phenolic resins 1 to 6 were used.

Phenolic resin-based curing agent 1: Phenol-novolac type phenolic resin (PR-HF-3 manufactured by Sumitomo Bakelite Co., Ltd., hydroxyl group equivalent: 102 g/eq, softening point: 80° C., ICI viscosity at 150° C.: 1.08 dPa·sec).

Phenolic resin-based curing agent 2: Phenol-aralkyl type phenolic resin having a phenylene skeleton (MILEX XLC-4L manufactured by Mitsui Chemicals, Inc., hydroxyl group equivalent: 168 g/eq, softening point: 62° C., ICI viscosity at 150° C.: 0.76 dPa·sec).

Phenolic resin-based curing agent 3: Phenol-aralkyl type phenolic resin having a biphenylene skeleton (GPH-65 manufactured by Nippon Kayaku Co., Ltd., hydroxyl group equivalent: 203 g/eq, softening point: 67° C., ICI viscosity at 150° C.: 0.68 dPa·sec).

Phenolic resin-based curing agent 4: Triphenolmethane type resin phenolic resin (MEH-7500 manufactured by Meiwa Chemical Co., Ltd., hydroxyl group equivalent: 97 g/eq, softening point: 110° C., ICI viscosity at 150° C.: 5.8 dPa·sec).

Phenolic resin-based curing agent 5: In a separable flask equipped with a stirring device, a thermometer, a reflux cooler, and a nitrogen inlet port, 116.3 parts by mass of a 37% aqueous solution of formaldehyde (manufactured by Wako Pure Chemical Industries, Ltd., formalin 37%), 37.7 parts by mass of sulfuric acid at a concentration of 98% by mass, and 100 parts by mass of m-xylene (special grade reagent manufactured by Kanto Chemical Co., Inc., m-xylene, boiling point: 139° C., molecular weight: 106, purity: 99.4%) were weighed, and then heating was started while the flask was purged with nitrogen. While the temperature inside the system was maintained in a temperature range of 90° C. to 100° C., the reaction mixture was stirred for 6 hours. The reaction mixture was cooled to room temperature, and then the system was neutralized by slowly adding 150 parts by mass of a 20 mass % sodium hydroxide solution thereto. To this reaction system, 839 parts by mass of phenol, and 338 parts by mass of α,α′-dichloro-p-xylene were added, and the mixture was heated while the reaction system was purged with nitrogen and stirred. While the temperature inside the system was maintained in the range of 110° C. to 120° C., the reaction mixture was allowed to react for 5 hours. The hydrochloric acid gas generated in the system as a result of the reaction described above was discharged out of the system by means of a nitrogen gas stream. After completion of the reaction, unreacted components and water were distilled off under reduced pressure conditions at 150° C. and 2 mmHg. Subsequently, 200 parts by mass of toluene was added to the system to uniformly dissolve the system, and then the solution was transferred into a separatory funnel. An operation (water washing) of adding 150 parts by mass of distilled water, shaking the separatory funnel, and then discarding the aqueous layer was repeated until the washing water became neutral. Subsequently, volatile components such as toluene and residual unreacted components were distilled off from the oil layer under reduced pressure conditions at 125° C. and 2 mmHg. Thus, a phenolic resin-based curing agent 5 represented by formula (12) (hydroxyl group equivalent: 175 g/eq, softening point: 64° C., ICI viscosity at 150° C.: 0.40 dPa·s; a mixture of polymers in which p in formula (12) represents an integer from 0 to 20, q represents an integer from 0 to 20, and r represents an integer from 0 to 20, while the average values of p, q and r are 1.8, 0.3, and 0.6, respectively. Furthermore, in the formula (12), the left terminal of the molecule is a hydrogen atom, and the right terminal is a phenol structure or a xylene structure) was obtained.

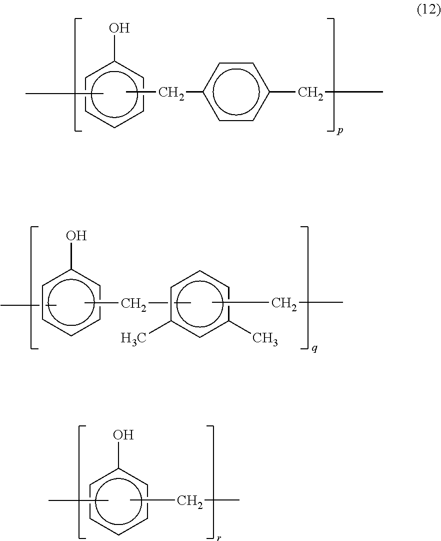

Phenolic resin-based curing agent 6: In a separable flask equipped with a stirring device, a thermometer, a reflux cooler, and a nitrogen inlet port, 100 parts by mass of 1,6-naphthalenediol (manufactured by Tokyo Chemical Industry Co., Ltd., melting point: 136° C., molecular weight: 160.2, purity: 99.5%), 31.5 parts by mass of 4,4′-bischloromethylbiphenyl (manufactured by Wako Pure Chemical Industries, Ltd., purity: 97.5%, molecular weight: 251), and 0.6 parts by mass of pure water were weighed, and then the mixture was heated while the system was purged with nitrogen. Upon the initiation of melting, stirring was started. While the temperature inside the system was maintained in the range of 150° C. to 160° C., the system was allowed to react for 2 hours. During the reaction described above, the hydrochloric acid generated in the system as a result of the reaction was discharged out of the system by means of a nitrogen gas stream. After completion of the reaction, residual hydrochloric acid and water were distilled off under reduced pressure conditions at 150° C. and 2 mmHg. Thus, a phenolic resin-based curing agent 6 represented by formula (13) (hydroxyl group equivalent: 102 g/eq, softening point: 75° C., ICI viscosity at 150° C.: 1.15 dPa·s, content proportion of u=0 calculated by the GPC area method: 51%, content proportion of u=0 to 2: 95%, average value of u: 0.72) was obtained.

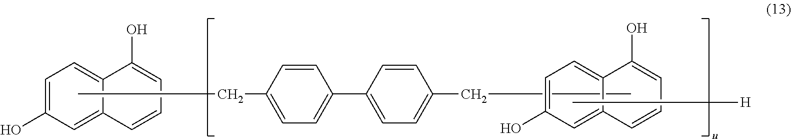

The ICI viscosities of the epoxy resins 1 to 3 and the phenolic resin-based curing agents 1 to 6 were measured by using an ICI cone-plate viscometer manufactured by MST Engineering, Ltd.

As the inorganic filler material (C), a blend (inorganic filler material 1) of 87.7% by mass of fused spherical silica FB560 (average particle size: 30 μm) manufactured by Denki Kagaku Kogyo K.K., 5.7% by mass of synthetic spherical silica SO-C2 (average particle size: 0.5 μm) manufactured by Admatechs Co., Ltd., and 6.6% by mass of synthetic spherical silica SO-C5 (average particle size: 30 μm) manufactured by Admatechs Co., Ltd., was used.

As the curing accelerator (D), curing accelerators 1 and 2 shown below were used.

Curing accelerator 1: Curing accelerator represented by formula (14)

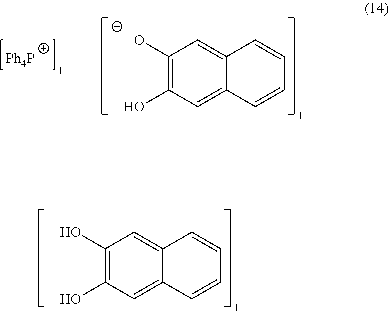

Curing accelerator 2: Curing accelerator represented by formula (15)

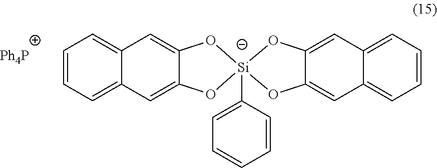

As the coupling agent (F), silane coupling agents 1 to 3 shown below were used.

Silane coupling agent 1: γ-mercaptopropyltrimethoxysilane (manufactured by Shin-Etsu Chemical Co., Ltd., KBM-803)

Silane coupling agent 2: γ-glycidoxypropyltrimethoxysilane (manufactured by Shin-Etsu Chemical Co., Ltd., KBM-403)

Silane coupling agent 3: N-phenyl-3-aminopropyltrimethoxysilane (manufactured by Shin-Etsu Chemical Co., Ltd., KBM-573)

As the inorganic flame retardant (G), aluminum hydroxide (manufactured by Sumitomo Chemical Co., Ltd., CL-303) was used.

As the colorant, carbon black (MA600) manufactured by Mitsubishi Chemical Corp. was used.

As the releasing agent, carnauba wax (NIKKO CARNAUBA, melting point: 83° C.) manufactured by Nikko Fine Products Co., Ltd. was used.

### Example 1

The following components were mixed in a mixer at normal temperature, and melt kneading was carried out using a heated roll at 80° C. to 100° C. Thereafter, the kneading product was cooled and then pulverized, and thus a resin composition was obtained.

| | | |
|---|---|---|
| Epoxy resin 1 | 8.83 | parts by mass |
| Phenolic resin-based curing agent 1 | 3.67 | parts by mass |
| Inorganic filler material 1 | 86.5 | parts by mass |
| Curing accelerator 1 | 0.4 | parts by mass |
| Silane coupling agent 1 | 0.1 | parts by mass |
| Silane coupling agent 2 | 0.05 | parts by mass |
| Silane coupling agent 3 | 0.05 | parts by mass |
| Carbon black | 0.3 | parts by mass |
| Carnauba wax | 0.1 | parts by mass |

The resin composition thus obtained was evaluated for the following items. The evaluation results are presented in Table 1.

Evaluation Items

Spiral flow: The resin composition for semiconductor encapsulation obtained as described above was injected into a mold for spiral flow measurement according to EMMI-1-66 under the conditions of 175° C., an injection pressure of 6.9 MPa, and a pressure dwell of 120 seconds, using a low pressure transfer molding machine (manufactured by Kohtaki Precision Machine Co., Ltd., KTS-15), and the flow length was measured. The spiral flow is a parameter of fluidity, and a larger value represents satisfactory fluidity. The unit is cm. The resin composition obtained in Example 1 exhibited 75 cm.

Continuous moldability: 7.5 g of the resin composition obtained as described above was charged into the tabletting mold having a size of Φ16 mm in a rotary tabletting machine, and tabletting was performed at a tabletting pressure of 600 Pa. Thus, tablets were obtained. The tablets were charged in a tablet supply magazine, and the magazine was placed in the inside of a molding apparatus. A molding process of obtaining a semiconductor device of 208-pin QFP (a lead frame made of Cu, outer dimension of package: 28 mm×28 mm×3.2 mm thick, pad size: 15.5 mm×15.5 mm, chip size: 15.0 mm×15.0 mm×0.35 mm thick) by encapsulating a silicon chip or the like by means of the tablets of the resin composition under the conditions of a mold temperature of 175° C., an injection pressure of 9.8 MPa, and a curing time of 60 seconds, using a low pressure automatic transfer molding machine (manufactured by Scinex Corp., SY-COMP), was carried out continuously up to 300 shots. At this time, the molding state (presence or absence of non-filling) of the semiconductor device was confirmed after every 25 shots, and a resin composition with which the continuous molding process was enabled for 500 shots or more was rated as 0; a resin composition with which the continuous molding process was enabled for equal to or more than 300 shots and fewer than 500 shots was rated as Δ; and a resin composition with which the continuous molding process was enabled for fewer than 300 shots was rated as x. The resin composition obtained in Example 1 enabled the continuous molding process for 500 shots or more and exhibited satisfactory continuous moldability.

Adherence test: A resin composition thus obtained was tabletted at a tabletting pressure of 600 Pa using a powder molding press machine (manufactured by Tamagawa Machinery Co., Ltd., S-20-A) by adjusting the conditions to a mass of 15 g and a size of φ 18 mm×height of about 30 mm, and tablets were obtained. In order to perform continuous molding, a tablet supply magazine charged with the tablets thus obtained was mounted inside the molding apparatus, but the tablets in the magazine mounted in the molding apparatus were in a standby status inside the magazine of the molding apparatus until the tablets were actually used in molding, and up to 13 tablets were in a state of being vertically stacked at a surface temperature of about 35° C. For the supply and conveyance of the tablets inside the molding apparatus, when a push-up pin is elevated from the lowermost part of the magazine, the uppermost tablet is pushed out from the upper part of the magazine, lifted by a mechanical arm, and conveyed to a pot for transfer molding. At this time, if the tablets adhere in the up and down directions while waiting in the magazine, conveyance failure occurs.

As this adherence test, 13 molded tablets are vertically stacked in the magazine and are left to stand at 35° C. for 8 hours, and then the state of adherence is confirmed. A case where the tablets were not adhering was rated as ∘; a case where slight adherence occurred but the tablets were easily detached was rated as Δ; and a case where the tablets simply did not come off was rated as x. The epoxy resin composition obtained in Example 1 does not exhibit adherence between the tablets, and continuous molding may be easily carried out. If such adherence of tablets occurs, an accurate number of tablets may not be conveyed in an encapsulation molding process for semiconductor devices, and this causes equipment stoppage.

Flame resistance: A resin composition for semiconductor encapsulation was injection molded using a low pressure transfer molding machine (manufactured by Kohtaki Precision Machine Co., Ltd., KTS-30) under the conditions of a mold temperature of 175° C., an injection time of 15 seconds, a curing time of 120 seconds, and an injection pressure of 9.8 MPa. Thus, a flame resistant specimen having a thickness of 3.2 mm was produced and heat treated at 175° C. for 4 hours. The specimen thus obtained was subjected to a flame resistance test according to the standards of the UL94 vertical method. The flame resistance ranks after judgment are indicated in the table. The resin composition for semiconductor encapsulation obtained in Example 1 exhibited satisfactory flame resistance with Fmax: 4 seconds, ΣF: 11 seconds, and flame resistance rank: V-0.

Solder resistance test 1: A lead frame mounted with a semiconductor element (silicon chip) or the like was encapsulated by injecting a resin composition for semiconductor encapsulation, using a low pressure transfer molding machine (manufactured by Dai-ichi Seiko Co., Ltd., GP-ELF) under the conditions of a mold temperature of 180° C., an injection pressure of 7.4 MPa, and a curing time of 120 seconds. Thus, 80pQFP semiconductor devices (Quad Flat Package, a lead frame made of Cu oxide spot, size: 14×20 mm×thickness 2.00 mm, semiconductor element: 7×7 mm×thickness 0.35 mm; the semiconductor element is bonded to the inner lead section of the lead frame with a gold wire having a diameter of 25 μm) were produced. Six semiconductor devices that had been heat treated at 175° C. for 4 hours were treated for 192 hours at 30° C. and a relative humidity of 60%, and then an IR reflow treatment (260° C., according to JEDEC Level 3 conditions) was carried out. The presence or absence of peeling and cracking in the interior of these semiconductor devices was observed with an ultrasonic reflectoscope (manufactured by Hitachi Construction Machinery Co., Ltd., MI-SCOPE 10), and a semiconductor device in which any one of peeling and cracking had occurred was considered to be defective. When the number of defective semiconductor devices was n, it was indicated as n/6. The semiconductor devices obtained in Example 1 resulted in a number of 0/6, and exhibited satisfactory reliability.

Solder resistance test 2: A test was carried out in the same manner as in the solder resistance test 1, except that six semiconductor devices that had been heat treated at 175° C. for 4 hours in the solder resistance test 1 described above were treated for 96 hours at 30° C. and a relative humidity of 60%. The semiconductor devices obtained in Example 1 resulted in a number of 0/6, and exhibited satisfactory reliability.

High temperature storage characteristics: A lead frame mounted with a semiconductor element (silicon chip) or the like was encapsulated by injecting a resin composition for semiconductor encapsulation using a low pressure transfer molding machine (manufactured by Dai-ichi Seiko Co., Ltd., GP-ELF) under the conditions of a mold temperature of 180° C., an injection pressure of 6.9±0.17 MPa, for 90 seconds. Thus, 16-pin type DIP semiconductor devices (Dual Inline Package, a lead frame made of 42 alloy, size: 7 mm×11.5 mm×thickness 1.8 mm, semiconductor element: 5×9 mm×thickness 0.35 mm; the semiconductor element has an oxide layer having a thickness of 5 μm formed on the surface, and a line-and-space aluminum wiring pattern with a line width of 10 μm further formed on the oxide layer, and the aluminum wiring pad unit on the element and the lead frame pad unit are bonded with a gold wire having a diameter of 25 μm) were produced. The initial resistance values of ten semiconductor devices that had been heat treated at 175° C. for 4 hours as a post-cure were measured, and the semiconductor devices were subjected to a high temperature storage treatment at 185° C. for 1000 hours. After the high temperature treatment, the resistance values of the semiconductor devices were measured. A semiconductor device which had an initial resistance value of 130% or higher was considered to be defective, and a case where the number of defective semiconductor devices was 0 was indicated as 0, while a case where the number of defective semiconductor devices was 1 to 10 was indicated as x. The semiconductor devices obtained in Example 1 resulted in a number of 0/10, and exhibited satisfactory reliability.

### Examples 2 to 12 and Comparative Examples 1 to 4

Resin compositions for semiconductor encapsulation were prepared in the same manner as in Example 1, according to the formulations indicated in Table 2, Table 3 and Table 4, and the resin compositions were evaluated in the same manner as in Example 1. The evaluation results are presented in Table 2, Table 3 and Table 4.

TABLE 2

| | Examples | | | | | |
|---|---|---|---|---|---|---|
| | 1 | 2 | 3 | 4 | 5 | 6 |
| Epoxy resin 1 | 8.83 | 7.42 | 6.84 | 8.96 | 7.30 | 8.83 |
| Epoxy resin 2 | | | | | | |
| Epoxy resin 3 | | | | | | |
| Phenolic resin-based | 3.67 | | | | | |
| curing agent 1 | | | | | | |
| Phenolic resin-based | | 5.08 | | | | |
| curing agent 2 | | | | | | |
| Phenolic resin-based | | | 5.66 | | | |
| curing agent 3 | | | | | | |
| Phenolic resin-based | | | | 3.54 | | |
| curing agent 4 | | | | | | |
| Phenolic resin-based | | | | | 5.20 | |
| curing agent 5 | | | | | | |
| Phenolic resin-based | | | | | | 3.67 |
| curing agent 6 | | | | | | |
| Inorganic filler 1 | 86.5 | 86.5 | 86.5 | 86.5 | 86.5 | 86.5 |
| Curing accelerator 1 | 0.4 | 0.4 | 0.4 | 0.4 | 0.4 | 0.4 |
| Curing accelerator 2 | | | | | | |
| Silane coupling agent 1 | 0.1 | 0.1 | 0.1 | 0.1 | 0.1 | 0.1 |
| Silane coupling agent 2 | 0.05 | 0.05 | 0.05 | 0.05 | 0.05 | 0.05 |
| Silane coupling agent 3 | 0.05 | 0.05 | 0.05 | 0.05 | 0.05 | 0.05 |
| Aluminum hydroxide | | | | | | |
| Carbon black | 0.3 | 0.3 | 0.3 | 0.3 | 0.3 | 0.3 |
| Carnauba wax | 0.1 | 0.1 | 0.1 | 0.1 | 0.1 | 0.1 |
| Spiral flow (cm) | 75 | 77 | 72 | 70 | 83 | 72 |
| Continuous moldability | ∘ | ∘ | ∘ | ∘ | ∘ | ∘ |
| Resistance to adherence | ∘ | ∘ | ∘ | ∘ | ∘ | ∘ |
| Flame resistance class | V-0 | V-0 | V-0 | V-0 | V-0 | V-0 |
| Solder resistance test 1 | 0/6 | 0/6 | 0/6 | 0/6 | 0/6 | 0/6 |
| (number of defective | | | | | | |
| devices among n = 6) | | | | | | |
| Solder resistance test 2 | 0/6 | 0/6 | 0/6 | 0/6 | 0/6 | 0/6 |
| (number of defective | | | | | | |
| devices among n = 6) | | | | | | |
| High temperature storage | 0/10 | 0/10 | 0/10 | 0/10 | 0/10 | 0/10 |
| characteristics (HTSL) | ∘ | ∘ | ∘ | ∘ | ∘ | ∘ |

TABLE 3

| Examples | | | | | |
|---|---|---|---|---|---|
| 7 | 8 | 9 | 10 | 11 | 12 |

| | | | | | | |
|---|---|---|---|---|---|---|
| Epoxy resin 1 | | | 8.07 | 8.83 | 8.83 | 8.83 |
| Epoxy resin 2 | 8.73 | 7.31 | | | | |
| Epoxy resin 3 | | | | | | |
| Phenolic resin-based | 3.77 | | 2.21 | | 3.67 | 3.67 |
| curing agent 1 | | | | | | |
| Phenolic resin-based | | | 2.22 | | | |
| curing agent 2 | | | | | | |
| Phenolic resin-based | | 5.19 | | 1.84 | | |
| curing agent 3 | | | | | | |
| Phenolic resin-based | | | | 1.83 | | |
| curing agent 4 | | | | | | |
| Phenolic resin-based | | | | | | |
| curing agent 5 | | | | | | |
| Phenolic resin-based | | | | | | |
| curing agent 6 | | | | | | |
| Inorganic filler 1 | 86.5 | 86.5 | 86.5 | 86.5 | 86.5 | 84.5 |
| Curing accelerator 1 | 0.4 | 0.4 | 0.4 | 0.4 | | 0.4 |
| Curing accelerator 2 | | | | | 0.4 | |
| Silane coupling agent 1 | 0.1 | 0.1 | 0.1 | 0.1 | 0.1 | 0.1 |
| Silane coupling agent 2 | 0.05 | 0.05 | 0.05 | 0.05 | 0.05 | 0.05 |
| Silane coupling agent 3 | 0.05 | 0.05 | 0.05 | 0.05 | 0.05 | 0.05 |
| Aluminum hydroxide | | | | | | 2 |
| Carbon black | 0.3 | 0.3 | 0.3 | 0.3 | 0.3 | 0.3 |
| Carnauba wax | 0.1 | 0.1 | 0.1 | 0.1 | 0.1 | 0.1 |
| Spiral flow (cm) | 78 | 74 | 77 | 72 | 80 | 76 |
| Continuous moldability | ∘ | ∘ | ∘ | ∘ | ∘ | ∘ |
| Resistance to adherence | ∘ | ∘ | ∘ | ∘ | ∘ | ∘ |
| Flame resistance class | V-0 | V-0 | V-0 | V-0 | V-0 | V-0 |
| Solder resistance test 1 | 0/6 | 0/6 | 0/6 | 0/6 | 0/6 | 0/6 |
| (number of defective | | | | | | |
| devices among n = 6) | | | | | | |
| Solder resistance test 2 | 0/6 | 0/6 | 0/6 | 0/6 | 0/6 | 0/6 |
| (number of defective | | | | | | |
| devices among n = 6) | | | | | | |
| High temperature storage | 0/10 | 0/10 | 0/10 | 0/10 | 0/10 | 0/10 |
| characteristics (HTSL) | ∘ | ∘ | ∘ | ∘ | ∘ | ∘ |

TABLE 4

| | Comparative Examples | | | |
|---|---|---|---|---|
| | 1 | 2 | 3 | 4 |
| Epoxy resin 1 | | | | |
| Epoxy resin 2 | | | | |
| Epoxy resin 3 | 8.65 | 7.21 | 6.62 | 8.78 |
| Phenolic resin-based | 3.85 | | | |
| curing agent 1 | | | | |
| Phenolic resin-based | | 5.29 | | |
| curing agent 2 | | | | |
| Phenolic resin-based | | | 5.88 | |
| curing agent 3 | | | | |
| Phenolic resin-based | | | | 3.72 |
| curing agent 4 | | | | |
| Phenolic resin-based | | | | |
| curing agent 5 | | | | |
| Phenolic resin-based | | | | |
| curing agent 6 | | | | |
| Inorganic filler 1 | 86.5 | 86.5 | 86.5 | 86.5 |
| Curing accelerator 1 | 0.4 | 0.4 | 0.4 | 0.4 |
| Curing accelerator 2 | | | | |
| Silane coupling agent 1 | 0.1 | 0.1 | 0.1 | 0.1 |
| Silane coupling agent 2 | 0.05 | 0.05 | 0.05 | 0.05 |
| Silane coupling agent 3 | 0.05 | 0.05 | 0.05 | 0.05 |
| Aluminum hydroxide | | | | |
| Carbon black | 0.3 | 0.3 | 0.3 | 0.3 |
| Carnauba wax | 0.1 | 0.1 | 0.1 | 0.1 |
| Spiral flow (cm) | 78 | 80 | 74 | 72 |
| Continuous moldability | Δ | x | x | Δ |
| Resistance to adherence | Δ | x | x | Δ |
| Flame resistance class | V-0 | V-0 | V-0 | V-0 |
| Solder resistance test 1 | 6/6 | 6/6 | 3/6 | 6/6 |
| (number of defective | | | | |
| devices among n = 6) | | | | |
| Solder resistance test 2 | 3/6 | 0/6 | 0/6 | 3/6 |
| (number of defective | | | | |
| devices among n = 6) | | | | |
| High temperature storage | 2/10 | 5/10 | 3/10 | 0/10 |
| characteristics (HTSL) | x | x | x | ∘ |

Examples 1 to 12 were resin compositions containing an epoxy resin (A-1) represented by the formula (1), a phenolic resin-based curing agent (B), and an inorganic filler material (C), and included resin compositions in which the molecular weight distribution of the epoxy resin (A-1) was changed; the type of the phenolic resin (B) was changed; two kinds of phenolic resins (B) were used in combination; the type of the curing accelerator (D) was changed; or an inorganic flame retardant (G) was added. However, in all of these resin compositions, results with an excellent balance among fluidity (spiral flow), continuous moldability, resistance to adherence, flame resistance, resistance to solder, and high temperature storage characteristics were obtained.

On the other hand, in Comparative Examples 1 to 4 that used the phenolphthalein type epoxy resin 3, which was different from the epoxy resin (A-1) represented by the formula (1), the resin compositions were affected by the combined phenolic resin-based curing agent, and resulted in deterioration of at least any one of continuous moldability, resistance to adherence, resistance to solder, and high temperature storage characteristics. In Comparative Examples 2 and 3 that used the phenolic resin-based curing agents 2 and 3 having relatively low softening points, adherence between tablets easily occurred in the adherence test, and since these curing agents have low curability, results with poor continuous moldability were obtained. Even in Comparative Example 4 that used the triphenolmethane type phenolic resin-based curing agent 4 having a high softening point and excellent curability and heat resistance, the high temperature storage characteristics were good, but the results were not as satisfactory as the results of the Examples in terms of the continuous moldability, resistance to adherence, and resistance to solder.

According to the results described above, only in the resin compositions that used the epoxy resin (A-1) of the present invention, results with an excellent balance among fluidity (spiral flow), continuous moldability, resistance to adherence, flame resistance, resistance to solder, and high temperature storage characteristics were obtained, even under the combination with various phenolic resin-based curing agents. Thus, when compared with the resin compositions that used phenolphthalein type epoxy resins which are different from the epoxy resin (A-1) represented by the formula (1), the Examples provide remarkable effects that surpass the extent that may be predicted or expected.

In the following Examples 13 to 24 and Comparative Examples 5 to 10, resin compositions containing the components indicated in Tables 5 to 7 in predetermined amounts of incorporation were prepared, and the resin compositions were evaluated in terms of the spiral flow, flame resistance, water absorption rate, continuous moldability, resistance to solder, and high temperature storage characteristics.

As the epoxy resin, the following epoxy resins 4 to 8 were used.

Among these, epoxy resin 4 corresponds to the epoxy resin (A-1).

Epoxy Resin 4:

In a separable flask equipped with a stirring device, a thermometer, a reflux cooler, and a nitrogen inlet port, 100 parts by mass of phenolphthalein (manufactured by Tokyo Chemical Industry Co., Ltd.), and 350 parts by mass of epichlorohydrin (manufactured by Tokyo Chemical Industry Co., Ltd.) were weighed, and the mixture was dissolved by heating to 90° C. Subsequently, 50 parts by mass of sodium hydroxide (solid fine particulate form, 99% purity reagent) was slowly added thereto over 4 hours, and the resulting mixture was heated to 100° C. and allowed to react for 2 hours. At the time point when the color of the solution turned yellow, the reaction was terminated. After the reaction, an operation (water washing) of adding 150 parts by mass of distilled water, shaking the reaction mixture, and then discarding the aqueous layer was repeatedly carried out until the washing water became neutral. Subsequently, epichlorohydrin was distilled off from the oil layer under reduced pressure conditions of 125° C. and 2 mmHg. The solid thus obtained was dissolved by adding 250 parts by mass of methyl isobutyl ketone, and the solution was heated to 70° C. 13 parts by mass of a 30 mass % aqueous solution of sodium hydroxide was added thereto over one hour, and the mixture was allowed to react for another one hour. The reaction mixture was left to stand, and the aqueous layer was discarded. 150 parts by mass of distilled water was added to the oil layer to carry out a water washing operation, and the same water washing operation was repeated until the washing water became neutral. Subsequently, methyl isobutyl ketone was distilled off by heating under reduced pressure. Thus, an epoxy resin 4 containing a compound represented by the formula (11) (epoxy equivalent: 235 g/eq, softening point: 67° C., ICI viscosity at 150° C.: 1.1 dPa·sec) was obtained. The GPC chart of the epoxy resin 4 is presented in FIG. 6. From the GPC results, it was confirmed that in the compound represented by the formula (11), a n=0 component is contained at a proportion of 86% by area, and a n=1 component, a n=2 component, and other side products are contained at a proportion of 14% by area in total.

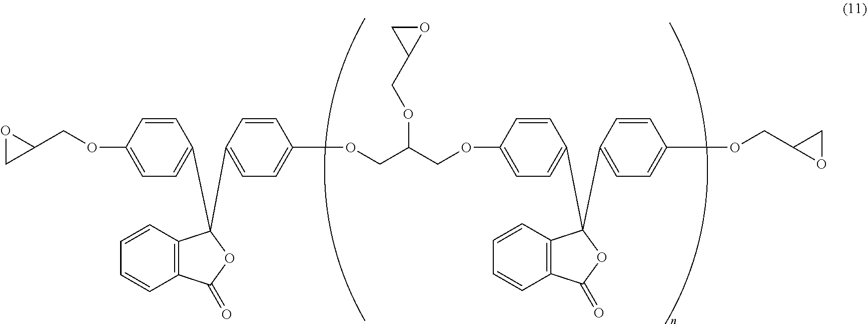

Epoxy resin 5: Triphenolmethane type epoxy resin (manufactured by Mitsubishi Chemical Corp., E-1032H60, hydroxyl group equivalent: 171 g/eq, softening point: 59° C., ICI viscosity at 150° C.: 1.30 dPa·sec)

Epoxy resin 6: Ortho-cresol-novolac type epoxy resin (manufactured by DIC Corp., EPLICLON N660, hydroxyl group equivalent: 210 g/eq, softening point: 62° C., ICI viscosity at 150° C.: 2.34 dPa·sec)

Epoxy resin 7: Phenol-aralkyl type epoxy resin having a phenylene skeleton (manufactured by Nippon Kayaku Co., Ltd., NC-2000, hydroxyl group equivalent: 238 g/eq, softening point: 52° C., ICI viscosity at 150° C.: 1.2 dPa·sec)

Epoxy resin 8: Phenol-aralkyl type epoxy resin having a biphenylene skeleton (manufactured by Nippon Kayaku Co., Ltd., NC-3000, hydroxyl group equivalent: 276 g/eq, softening point: 57° C., ICI viscosity at 150° C.: 1.11 dPa·sec)

The GPC analysis of the epoxy resin 4 was carried out under the following conditions. 20 mg of a sample of the epoxy resin 4 was sufficiently dissolved by adding 6 ml of solvent tetrahydrofuran (THF), and the solution was submitted to the GPC analysis. A GPC system in which Module W2695 manufactured by Waters Corp., TSKGUARDCOLUMNHHR-L (diameter: 6.0 mm, pipe length: 40 mm, a guard column) manufactured by Tosoh Corp., two TSK-GEL GMHHR-L (diameter: 7.8 mm, pipe length: 30 mm, a polystyrene gel column) manufactured by Tosoh Corp., and a differential refractive index (R1) detector W2414 manufactured by Waters Corp. were connected in series was used. The flow rate of the pump was 0.5 ml/min, the temperature in the columns and the differential refractive index detector was set to 40° C., and an analysis was carried out by injecting a measurement solution using a 100-μl injector.

As the phenolic resin as the curing agent (B), phenolic resins 2 to 9 were used. Phenolic resins 2 to 6 were the same as described above.

Among these, the phenolic resin-based curing agents 4 and 9 correspond to the phenolic resin (B-1), while the phenolic resin-based curing agents 6, 7 and 8 correspond to the naphthol resin (B-2).

Phenolic resin-based curing agent 7: A copolymer type resin of a naphthol-novolac resin and a cresol-novolac resin (KAYAHARED CBN manufactured by Nippon Kayaku Co., Ltd., hydroxyl group equivalent: 139 g/eq, softening point: 90° C., ICI viscosity at 150° C.: 1.65 dPa·sec)

Phenolic resin-based curing agent 8: A naphthol-aralkyl type phenolic resin having a phenylene skeleton (SN-485 manufactured by Tohto Kasei Co., Ltd., hydroxyl group equivalent: 210 g/eq, softening point: 87° C., ICI viscosity at 150° C.: 1.78 dPa·sec)

Phenolic resin-based curing agent 9: A copolymer type phenolic resin of a triphenolmethane type resin and a phenol-novolac resin (HE910-20 manufactured by Air Water, Inc., hydroxyl group equivalent: 101 g/eq, softening point: 88° C., ICI viscosity at 150° C.: 1.5 dPa·sec)

### Example 13

The following components were mixed in a mixer at normal temperature, and the mixture was melt kneaded with a heated roll at 80° C. to 100° C. Subsequently, the kneading product was cooled and pulverized, and thus a resin composition for semiconductor encapsulation was obtained.

| | | |
|---|---|---|
| Epoxy resin 4 | 8.97 | parts by mass |
| Phenolic resin-based curing agent 4 | 3.53 | parts by mass |
| Inorganic filler material 1 | 86.5 | parts by mass |
| Curing accelerator 1 | 0.4 | parts by mass |
| Silane coupling agent 1 | 0.1 | parts by mass |
| Silane coupling agent 2 | 0.05 | parts by mass |
| Silane coupling agent 3 | 0.05 | parts by mass |
| Carbon black | 0.3 | parts by mass |
| Carnauba wax | 0.1 | parts by mass |

The resin composition for semiconductor encapsulation thus obtained was evaluated for spiral flow, flame resistance, water absorption rate, continuous moldability, resistance to solder, and high temperature storage characteristics. The methods for evaluating the spiral flow, flame resistance, continuous moldability, resistance to solder, and high temperature storage characteristics are the same as described above. The evaluation results are presented in Table 5.

Boiling water absorption rate: A disc-shaped specimen having a diameter of 50 mm and a thickness of 3 mm was formed using a low pressure transfer molding machine (manufactured by Kohtaki Precision Machine Co., Ltd., KTS-30) at a mold temperature of 175° C., an injection pressure of 9.8 MPa, and a curing time of 120 s, and the specimen was heat treated at 175° C. for 4 hours. The mass change between the mass before the moisture absorption treatment of the specimen and the mass after a boiling water treatment in pure water for 24 hours was measured, and the water absorption rate of the specimen was calculated in percentage. The unit is mass %. The resin composition for semiconductor encapsulation obtained in Example 1 exhibited standard water absorption such as 0.249 mass %.

### Examples 14 to 24 and Comparative Examples 5 to 10

Resin compositions for semiconductor encapsulation were prepared in the same manner as in Example 13 according to the formulations indicated in Table 5, Table 6 and Table 7, and the resin compositions were evaluated in the same manner as in Example 13. The evaluation results are presented in Table 5, Table 6 and Table 7.

TABLE 5

| | Example | Example | Example | Example | Example | Example |
|---|---|---|---|---|---|---|
| | 13 | 14 | 15 | 16 | 17 | 18 |
| Epoxy resin 4 | 8.97 | 8 | 6.75 | 8.87 | 8.77 | 8.62 |
| Epoxy resin 5 | | | | | | |
| Epoxy resin 6 | | | | | | |
| Epoxy resin 7 | | | | | | |
| Epoxy resin 8 | | | | | | |
| Phenolic | 3.53 | | | | | 3.1 |
| resin-based | | | | | | |
| curing agent 4 | | | | | | |
| Phenolic | | 4.5 | | | | |
| resin-based | | | | | | |
| curing agent 7 | | | | | | |
| Phenolic | | | 5.75 | | | |
| resin-based | | | | | | |
| curing agent 8 | | | | | | |
| Phenolic | | | | 3.63 | | |
| resin-based | | | | | | |
| curing agent 9 | | | | | | |
| Phenolic | | | | | 3.73 | |
| resin-based | | | | | | |
| curing agent 6 | | | | | | |
| Phenolic | | | | | | 0.78 |
| resin-based | | | | | | |
| curing agent 2 | | | | | | |
| Phenolic | | | | | | |
| resin-based | | | | | | |
| curing agent 5 | | | | | | |
| Phenolic | | | | | | |
| resin-based | | | | | | |
| curing agent 3 | | | | | | |
| Inorganic filler 1 | 86.5 | 86.5 | 86.5 | 86.5 | 86.5 | 86.5 |
| Curing | 0.4 | 0.4 | 0.4 | 0.4 | 0.4 | 0.4 |
| accelerator 1 | | | | | | |
| Curing | | | | | | |
| accelerator 2 | | | | | | |
| Silane coupling | 0.1 | 0.1 | 0.1 | 0.1 | 0.1 | 0.1 |
| agent 1 | | | | | | |
| Silane coupling | 0.05 | 0.05 | 0.05 | 0.05 | 0.05 | 0.05 |
| agent 2 | | | | | | |
| Silane coupling | 0.05 | 0.05 | 0.05 | 0.05 | 0.05 | 0.05 |
| agent 3 | | | | | | |
| Aluminum | | | | | | |
| hydroxide | | | | | | |
| Carbon black | 0.3 | 0.3 | 0.3 | 0.3 | 0.3 | 0.3 |
| Carnauba wax | 0.1 | 0.1 | 0.1 | 0.1 | 0.1 | 0.1 |
| Spiral flow (cm) | 78 | 90 | 77 | 85 | 58 | 80 |
| Flame resistance | 31 | 16 | 4 | 29 | 24 | 11 |
| test ΣF (sec) | | | | | | |
| Flame resistance | 8 | 4 | 1 | 7 | 7 | 3 |
| test Fmax (sec) | | | | | | |
| Flame resistance | V-0 | V-0 | V-0 | V-0 | V-0 | V-0 |
| test class | | | | | | |
| Water absorption | 0.249 | 0.221 | 0.186 | 0.232 | 0.224 | 0.227 |
| rate (%) | | | | | | |
| Continuous | ∘ | ∘ | ∘ | ∘ | ∘ | ∘ |
| moldability | | | | | | |
| Solder resistance | 0/6 | 0/6 | 0/6 | 0/6 | 0/6 | 0/6 |
| test 1 (number of | | | | | | |
| defective devices | | | | | | |
| among n = 6) | | | | | | |
| Solder resistance | 0/6 | 0/6 | 0/6 | 0/6 | 0/6 | 0/6 |
| test 2 (number of | | | | | | |
| defective devices | | | | | | |
| among n = 6) | | | | | | |
| High temperature | 0/10 | 0/10 | 0/10 | 0/10 | 0/10 | 0/10 |
| storage | ∘ | ∘ | ∘ | ∘ | ∘ | ∘ |
| characteristics | | | | | | |
| (HTSL) | | | | | | |

TABLE 6

| | Example | Example | Example | Example | Example | Example |
|---|---|---|---|---|---|---|
| | 19 | 20 | 21 | 22 | 23 | 24 |
| Epoxy resin 4 | 8.57 | 8.43 | 7.07 | 7.25 | 8.97 | 8.97 |
| Epoxy resin 5 | | | 1.76 | | | |
| Epoxy resin 6 | | | | | | |
| Epoxy resin 7 | | | | | | |
| Epoxy resin 8 | | | | 1.81 | | |
| Phenolic | 3.14 | 3.26 | 3.67 | 3.44 | 3.53 | 3.53 |
| resin-based | | | | | | |
| curing agent 4 | | | | | | |
| Phenolic | | | | | | |
| resin-based | | | | | | |
| curing agent 7 | | | | | | |
| Phenolic | | | | | | |
| resin-based | | | | | | |
| curing agent 8 | | | | | | |
| Phenolic | | | | | | |
| resin-based | | | | | | |
| curing agent 9 | | | | | | |
| Phenolic | | | | | | |
| resin-based | | | | | | |
| curing agent 6 | | | | | | |
| Phenolic | | | | | | |
| resin-based | | | | | | |
| curing agent 2 | | | | | | |
| Phenolic | 0.79 | | | | | |
| resin-based | | | | | | |
| curing agent 5 | | | | | | |
| Phenolic | | 0.81 | | | | |
| resin-based | | | | | | |
| curing agent 3 | | | | | | |
| Inorganic filler 1 | 86.5 | 86.5 | 86.5 | 86.5 | 86.5 | 84.5 |
| Curing | 0.4 | 0.4 | 0.4 | 0.4 | | 0.4 |
| accelerator 1 | | | | | | |
| Curing | | | | | 0.4 | |
| accelerator 2 | | | | | | |
| Silane coupling | 0.1 | 0.1 | 0.1 | 0.1 | 0.1 | 0.1 |
| agent 1 | | | | | | |
| Silane coupling | 0.05 | 0.05 | 0.05 | 0.05 | 0.05 | 0.05 |
| agent 2 | | | | | | |
| Silane coupling | 0.05 | 0.05 | 0.05 | 0.05 | 0.05 | 0.05 |
| agent 3 | | | | | | |
| Aluminum | | | | | | 2 |
| hydroxide | | | | | | |
| Carbon black | 0.3 | 0.3 | 0.3 | 0.3 | 0.3 | 0.3 |
| Carnauba wax | 0.1 | 0.1 | 0.1 | 0.1 | 0.1 | 0.1 |
| Spiral flow (cm) | 92 | 88 | 81 | 83 | 82 | 79 |
| Flame resistance | 9 | 9 | 33 | 9 | 30 | 10 |
| test ΣF (sec) | | | | | | |
| Flame resistance | 3 | 3 | 9 | 3 | 7 | 3 |
| test Fmax (sec) | | | | | | |
| Flame resistance | V-0 | V-0 | V-0 | V-0 | V-0 | V-0 |
| test class | | | | | | |
| Water absorption | 0.211 | 0.187 | 0.258 | 0.204 | 0.245 | 0.262 |
| rate (%) | | | | | | |
| Continuous | ∘ | ∘ | ∘ | ∘ | ∘ | ∘ |
| moldability | | | | | | |
| Solder resistance | 0/6 | 0/6 | 0/6 | 0/6 | 0/6 | 0/6 |
| test 1 (number of | | | | | | |
| defective devices | | | | | | |
| among n = 6) | | | | | | |
| Solder resistance | 0/6 | 0/6 | 0/6 | 0/6 | 0/6 | 0/6 |
| test 2 (number of | | | | | | |
| defective devices | | | | | | |
| among n = 6) | | | | | | |
| High temperature | 0/10 | 0/10 | 0/10 | 0/10 | 0/10 | 0/10 |
| storage | ∘ | ∘ | ∘ | ∘ | ∘ | ∘ |
| characteristics | | | | | | |
| (HTSL) | | | | | | |

TABLE 7

| | Comparative | Comparative | Comparative | Comparative | Comparative | Comparative |
|---|---|---|---|---|---|---|
| | Example 5 | Example 6 | Example 7 | Example 8 | Example 9 | Example 10 |
| Epoxy resin 4 | | | | | | |
| Epoxy resin 5 | 8.12 | | | | | |
| Epoxy resin 6 | | 8.68 | | | | |
| Epoxy resin 7 | | | 9 | | 7.47 | |
| Epoxy resin 8 | | | | 9.37 | | 6.9 |
| Phenolic | 4.38 | 3.82 | 3.5 | 3.13 | | |
| resin-based | | | | | | |
| curing agent 4 | | | | | | |
| Phenolic | | | | | | |
| resin-based | | | | | | |
| curing agent 7 | | | | | | |
| Phenolic | | | | | | |
| resin-based | | | | | | |
| curing agent 8 | | | | | | |
| Phenolic | | | | | | |
| resin-based | | | | | | |
| curing agent 9 | | | | | | |
| Phenolic | | | | | | |
| resin-based | | | | | | |
| curing agent 6 | | | | | | |
| Phenolic | | | | | 5.03 | |
| resin-based | | | | | | |
| curing agent 2 | | | | | | |
| Phenolic | | | | | | |
| resin-based | | | | | | |
| curing agent 5 | | | | | | |
| Phenolic | | | | | | 5.6 |
| resin-based | | | | | | |
| curing agent 3 | | | | | | |
| Inorganic | 86.5 | 86.5 | 86.5 | 86.5 | 86.5 | 86.5 |
| filler 1 | | | | | | |
| Curing | 0.4 | 0.4 | 0.4 | 0.4 | 0.4 | 0.4 |
| accelerator 1 | | | | | | |
| Curing | | | | | | |
| accelerator 2 | | | | | | |
| Silane coupling | 0.1 | 0.1 | 0.1 | 0.1 | 0.1 | 0.1 |
| agent 1 | | | | | | |
| Silane coupling | 0.05 | 0.05 | 0.05 | 0.05 | 0.05 | 0.05 |
| agent 2 | | | | | | |
| Silane coupling | 0.05 | 0.05 | 0.05 | 0.05 | 0.05 | 0.05 |
| agent 3 | | | | | | |
| Aluminum | | | | | | |
| hydroxide | | | | | | |
| Carbon black | 0.3 | 0.3 | 0.3 | 0.3 | 0.3 | 0.3 |
| Carnauba wax | 0.1 | 0.1 | 0.1 | 0.1 | 0.1 | 0.1 |
| Spiral flow (cm) | 32 | 52 | 83 | 77 | 96 | 90 |
| Flame | 300 | 150 | 150 | 41 | 34 | 1 |
| resistance test | | | | | | |
| ΣF (sec) | | | | | | |
| Flame | 30 | 30 | 30 | 18 | 10 | 1 |
| resistance test | | | | | | |
| Fmax (sec) | | | | | | |
| Flame | Totally | Totally | Totally | V-1 | V-0 | V-0 |
| resistance test | burnt | burnt | burnt | | | |
| class | | | | | | |
| Water | 0.32 | 0.266 | 0.21 | 0.199 | 0.168 | 0.076 |
| absorption rate | | | | | | |
| (%) | | | | | | |
| Continuous | ∘ | ∘ | ∘ | ∘ | ∘ | x |
| moldability | | | | | | |
| Solder | 6/6 | 6/6 | 4/10 | 2/10 | 0/6 | 0/6 |
| resistance test | | | | | | |
| 1 (number of | | | | | | |
| defective | | | | | | |
| devices among n = | | | | | | |
| 6) | | | | | | |
| Solder | 4/6 | 3/6 | 0/10 | 0/10 | 0/6 | 0/6 |
| resistance test | | | | | | |
| 2 (number of | | | | | | |
| defective | | | | | | |
| devices among n = | | | | | | |
| 6) | | | | | | |
| High | 0/10 | 0/10 | 3/10 | 3/10 | 10/10 | 8/10 |
| temperature | ∘ | ∘ | x | x | x | x |
| storage | | | | | | |
| characteristics | | | | | | |
| (HTSL) | | | | | | |

Examples 13 to 24 were resin compositions containing an epoxy resin (A-1) represented by the formula (1), a phenolic resin (B-1) having a repeating unit structure containing two phenol skeletons or a naphthol resin (B-2) having a hydroxynaphthalene skeleton or a dihydroxynaphthalene skeleton, and an inorganic filler material (C), and included resin compositions in which an epoxy resin other than the epoxy resin (A-1) was used in combination; the type of the phenolic resin (B-1) or the naphtholic resin (B-2) was changed; a phenolic resin-based curing agent other than the phenolic resin (B-1) was used in combination; the type of the curing accelerator (D) was changed; and an inorganic flame retardant (G) was added. However, in all of these resin compositions, results with an excellent balance among fluidity (spiral flow), flame resistance, water absorption, resistance to solder, high temperature storage characteristics, and continuous moldability were obtained.

On the other hand, in Comparative Examples 5, 6, 7 and 8 in which a triphenolmethane type epoxy resin 5, an ortho-cresol-novolac type epoxy resin 6, a phenol-aralkyl type epoxy resin 7 having a phenylene skeleton, and a phenol-aralkyl type epoxy resin 8 having a biphenylene skeleton were used instead of the epoxy resin (A-1), and a phenolic resin 4 was used as the phenolic resin (B-1), results showed that a balance between high temperature storage characteristics and flame resistance could not be achieved. Furthermore, Comparative Example 9 that used the phenol-aralkyl type epoxy resin 7 having a phenylene skeleton and the phenol-aralkyl type phenolic resin 2 having a phenylene skeleton, and Comparative Example 10 that used a phenol-aralkyl type epoxy resin 8 having a biphenylene skeleton and a phenol-aralkyl type phenolic resin 3 having a biphenylene skeleton, were combinations intended to acquire high flame resistance and high resistance to solder. However, the resin compositions resulted in markedly poor high temperature storage characteristics.

According to the results described above, only in the resin compositions that used the epoxy resin (A) and the curing agent resin (B) of the present invention in combination, results with an excellent balance among fluidity (spiral flow), flame resistance, high temperature storage characteristics, resistance to solder, and continuous moldability were obtained. Thus, the Examples provide remarkable effects that surpass the extent that may be expected.

According to the present invention, since a resin composition for semiconductor encapsulation which exhibits flame resistance without using halogen compounds and antimony compounds, and has an excellent balance among continuous moldability, resistance to adherence, resistance to solder, and high temperature storage characteristics at a level higher than conventional cases, may be obtained, the resin composition is suitable for the encapsulation of semiconductor devices which are used in electronic instruments that are assumed to be used outdoors, and particularly for the encapsulation of semiconductor devices which are used in electronic instruments for vehicles where high temperature storage characteristics are required.

1. A resin composition for semiconductor encapsulation, comprising an epoxy resin (A), a curing agent (B), and an inorganic filler material (C), the epoxy resin (A) comprising an epoxy resin (A-1) represented by formula (1): 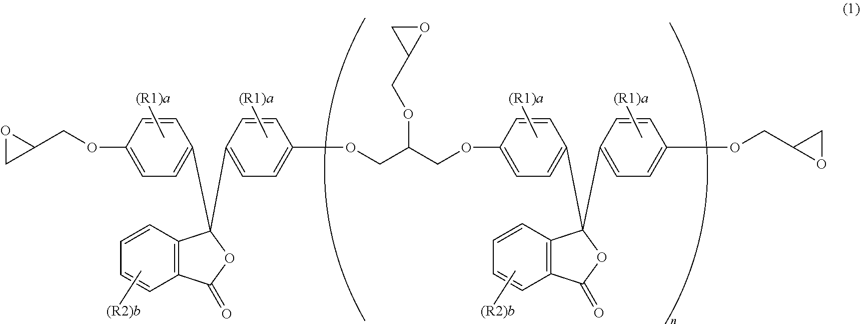
wherein in the formula (1), R1 represents a hydrocarbon group having 1 to 6 carbon atoms; R2 represents a hydrocarbon group having 1 to 6 carbon atoms, or an aromatic hydrocarbon group having 6 to 14 carbon atoms, while R1s and R2s may be respectively identical with or different from each other; a represents an integer from 0 to 4; b represents an integer from 0 to 4; and n represents an integer of 0 or greater,
wherein the epoxy resin (A-1) containing a component represented by the formula (1) in which n≧1, and a component (a1) represented by the formula (1) in which n=0.

2. The resin composition for semiconductor encapsulation according to claim 1,
wherein the epoxy resin (A-1) contains a component (a2) represented by the formula (1) in which n=1,
a peak intensity of the component (a1) measured by FD-MS is equal to or greater than 50% and equal to or less than 90% with respect to all the peaks of the epoxy resin (A-1), and a peak intensity of the component (a2) is equal to or greater than 10% and equal to or less than 50% with respect to all the peaks of the epoxy resin (A-1).

3. The resin composition for semiconductor encapsulation according to claim 2,
wherein the ratio P₂/P₁ of the peak intensity P₂, of the component (a2) to the peak intensity P₁, of the component (a1) as measured by FD-MS is equal to or higher than 0.1 and equal to or less than 1.0.

4. The resin composition for semiconductor encapsulation according to claim 1,
wherein a peak area of the component (a1) relative to the total peak area of the epoxy resin (A-1) obtained by gel permeation chromatography is equal to or greater than 70% by area and equal to or less than 95% by area.

5. The resin composition for semiconductor encapsulation according to claim 1,
wherein a ICI viscosity at 150° C. of the epoxy resin (A-1) is equal to or higher than 0.1 dPa·sec and equal to or lower than 3.0 dPa·sec.

6. The resin composition for semiconductor encapsulation according to claim 1,
wherein a softening point at 150° C. of the epoxy resin (A-1) is equal to or higher than 55° C. and equal to or lower than 90° C.

7. The resin composition for semiconductor encapsulation according to claim 1,
wherein an epoxy equivalent of the epoxy resin (A-1) is equal to or greater than 210 g/eq and equal to or less than 250 g/eq.

8. The resin composition for semiconductor encapsulation according to claim 1,
wherein the curing agent (B) is a phenolic resin-based curing agent.

9. The resin composition for semiconductor encapsulation according to claim 8,
wherein the phenolic resin-based curing agent includes at least one resin selected from a group consisting of a phenolic resin (B-1) having two or more phenolic skeletons, and a naphthol resin (B-2) having a hydroxynaphthalene skeleton or a dihydroxynaphthalene skeleton.

10. The resin composition for semiconductor encapsulation according to claim 9,
wherein the phenolic resin-based curing agent includes at least one resin selected from a group consisting of a phenolic resin (b1) represented by formula (2): 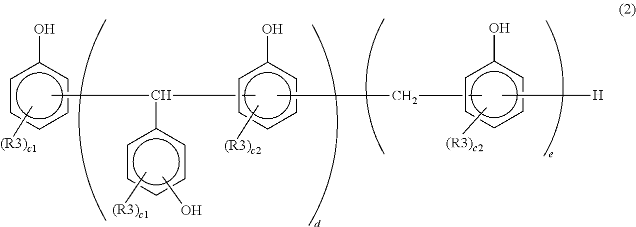
wherein in the formula (2), R3 represents a hydrocarbon group having 1 to 6 carbon atoms or an aromatic hydrocarbon group having 6 to 14 carbon atoms, while R3s may be identical with or different from each other; c1 represents an integer from 0 to 4; c2 represents an integer from 0 to 3, while c1s and c2s may be respectively identical with or different from each other; d represents an integer from 1 to 10; e represents an integer from 0 to 10; and a structural unit represented by a repetition number d and the structural unit represented by the repetition number e may be respectively lined up in a row, may be alternately arranged with each other, or may be arranged randomly;
a naphthol resin (b2) represented by formula (3): 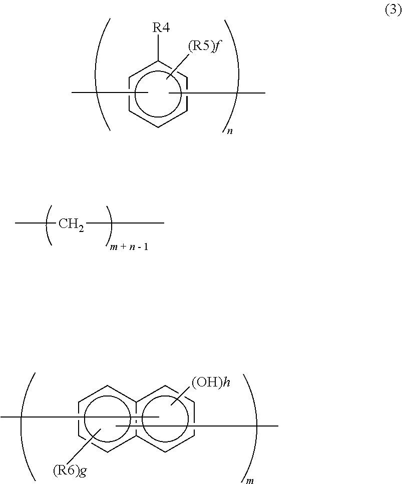
wherein in the formula (3), R4 represents a hydroxyl group or a hydrogen atom; R5 represents a hydrocarbon group having 1 to 6 carbon atoms, or an aromatic hydrocarbon group having 6 to 14 carbon atoms, while R4s and R5s may be respectively identical with or different from each other; R6 represents a hydrocarbon group having 1 to 6 carbon atoms, or an aromatic hydrocarbon group having 6 to 14 carbon atoms, while R6s may be identical with or different from each other; f represents an integer from 0 to 3; g represents an integer from 0 to 5; h represents an integer of 1 or 2; m and n each independently represents an integer from 1 to 10, while m+n≧2; and a structural unit represented by a repetition number m and the structural unit represented by the repetition number n may be respectively lined up in a row, may be alternately arranged with each other, or may be arranged randomly, but —CH₂— is essentially disposed between the respective structures, and
a naphthol resin (b3) represented by formula (4): 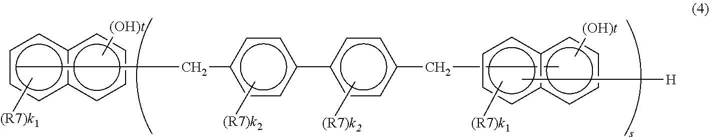
wherein in the formula (4), R7 represents a hydrocarbon group having 1 to 6 carbon atoms, or an aromatic hydrocarbon group having 6 to 14 carbon atoms, while R7s may be identical with or different from each other; k1 represents an integer from 0 to 6; k2 represents an integer from 0 to 4, while k1s and k2s may be respectively identical with or different from each other; s represents an integer from 0 to 10; and t represents an integer of 1 or 2.

11. The resin composition for semiconductor encapsulation according to claim 10,
wherein the amount of the at least one resin selected from the group consisting of the phenolic resin (b1), the naphthol resin (b2) and the naphthol resin (b3) is equal to or greater than 50 parts by mass and equal to or less than 100 parts by mass relative to 100 parts by mass of the curing agent (B).

12. The resin composition for semiconductor encapsulation according to claim 1,
wherein the amount of the inorganic filler material (C) is equal to or greater than 70% by mass and equal to or less than 93% by mass relative to the total mass of the resin composition for semiconductor encapsulation.

13. The resin composition for semiconductor encapsulation according to claim 1,
wherein the amount of the epoxy resin (A-1) is equal to or greater than 50 parts by mass and equal to or less than 100 parts by mass relative to 100 parts by mass of the epoxy resin (A).

14. The resin composition for semiconductor encapsulation according to claim 1, further comprising a curing accelerator (D).

15. The resin composition for semiconductor encapsulation according to claim 14,
wherein the curing accelerator (D) includes at least one curing accelerator selected from a group consisting of a tetrasubstituted phosphonium compound, a phosphobetaine compound, an adduct of a phosphine compound and a quinone compound, and an adduct of a phosphonium compound and a silane compound.

16. The resin composition for semiconductor encapsulation according to claim 1, further comprising a compound (E) in which two or more adjacent carbon atoms that constitute an aromatic ring are each bonded to a hydroxyl group.

17. The resin composition for semiconductor encapsulation according to claim 1, further comprising a coupling agent (F).

18. The resin composition for semiconductor encapsulation according to claim 1, further comprising an inorganic flame retardant (G).

19. A semiconductor device comprising a semiconductor element encapsulated with the resin composition for semiconductor encapsulation according to claim 1.
